(19) United States
(12) Patent Application Publication
(10) Pub. No.: US 2026/0013252 A1
(43) Pub. Date: Jan. 8, 2026

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventor: Youngkun JEE, Suwon-si (KR)

(73) Assignee: SAMSUNG ELECTRONICS CO., LTD., Suwon-si (KR)

(21) Appl. No.: 19/018,815

(22) Filed: Jan. 13, 2025

(30) Foreign Application Priority Data
Jul. 4, 2024 (KR) 10-2024-0088507

(51) Int. Cl. H10F 39/00; H01L 23/31; H01L 23/538; H01L 25/16; H10F 39/95

(52) U.S. Cl. CPC H10F 39/8063; H01L 23/3135; H01L 23/5385; H01L 25/167; H10F 39/95

(57) ABSTRACT

A semiconductor package including a package substrate; an intermediate substrate on the package substrate; an optical engine unit on the intermediate substrate; a logic device adjacent to the optical engine unit and on the intermediate substrate; and a memory device adjacent to the logic device and on the intermediate substrate, wherein the optical engine unit includes a first redistribution substrate, a photonic integrated circuit (PIC) chip on the first redistribution substrate, an electronic integrated circuit (EIC) chip on the PIC chip, a multi-insulating layer surrounding the PIC chip and the EIC chip, and a transparent support layer on the EIC chip and the multi-insulating layer.

### CROSS-REFERENCE TO RELATED APPLICATION

This application is based on and claims priority under 35 U.S.C. § 119 to Korean Patent Application No. 10-2024-0088507, filed on Jul. 4, 2024, in the Korean Intellectual Property Office, the disclosure of which is incorporated by reference herein in its entirety.

### BACKGROUND

Embodiments of the present disclosure relate to a semiconductor package and, more particularly, to a semiconductor package including a photonic integrated circuit (PIC).

In accordance with the development of the electronic industry, there has been a growing demand for high-functioning, high-speed, and miniaturized electronic components. Along with such demand, miniaturization and multi-functionality of semiconductor chips used in electronic components have been required. In addition, in the field of semiconductor packaging, the size of packages has been reduced due to miniaturized semiconductor chips. In response to the demand for improved performance of semiconductor packages and reduced form factors, structures of semiconductor packages have been developed for a multi-chip integration structure. Multi-chip integration refers to integration of chips having different functions from each other in a single semiconductor package. Recently, PIC chips and electronic integrated circuit (EIC) chips have been integrated in a single semiconductor package.

### SUMMARY

According to embodiments of the present disclosure, a semiconductor package may be provided and include an optical engine unit including a photonic integrated circuit (PIC) chip and an electronic integrated circuit (EIC) chip, and also a manufacturing method (e.g., process) thereof, which is simplified and which has improved reliability.

According to embodiments of the present disclosure, a semiconductor package may be provided and include: a package substrate; an intermediate substrate on the package substrate; an optical engine unit on the intermediate substrate; a logic device adjacent to the optical engine unit and on the intermediate substrate; and a memory device adjacent to the logic device and on the intermediate substrate, wherein the optical engine unit includes a first redistribution substrate, a photonic integrated circuit (PIC) chip on the first redistribution substrate, an electronic integrated circuit (EIC) chip on the PIC chip, a multi-insulating layer surrounding the PIC chip and the EIC chip, and a transparent support layer on the EIC chip and the multi-insulating layer.

According to embodiments of the present disclosure, a semiconductor package may be provided and include: a package substrate; an optical engine unit on the package substrate; a logic device adjacent to the optical engine unit and on the package substrate; and a memory device adjacent to the logic device and on the package substrate, wherein the optical engine unit includes a first redistribution substrate, a photonic integrated circuit (PIC) chip on the first redistribution substrate, an electronic integrated circuit (EIC) chip on the PIC chip, an insulating layer on the PIC chip, and a transparent support layer on the EIC chip and the insulating layer.

According to embodiments of the present disclosure, a semiconductor package may be provided and include: a package substrate; an intermediate substrate on the package substrate; an optical engine unit on the intermediate substrate; a logic device adjacent to the optical engine unit and on the intermediate substrate; and a memory device adjacent to the logic device and on the intermediate substrate, wherein the optical engine unit includes: a first redistribution substrate; a photonic integrated circuit (PIC) chip on the first redistribution substrate; an electronic integrated circuit (EIC) chip on the PIC chip; a first insulating layer on the first redistribution substrate and surrounding the PIC chip; a second insulating layer on the first insulating layer and the PIC chip and surrounding the EIC chip, the second insulating layer including an optic path block; and a transparent support layer on the EIC chip and the second insulating layer and including a microlens overlapping with the optic path block.

According to embodiments of the present disclosure, a method of manufacturing a semiconductor package may be provided and include: manufacturing an optical engine unit including a first redistribution substrate, a photonic integrated circuit (PIC) chip on the first redistribution substrate, an electronic integrated circuit (EIC) chip on the PIC chip, a multi-insulating layer surrounding the PIC chip and the EIC chip, and a transparent support layer on the EIC chip and the multi-insulating layer; mounting the optical engine unit on an intermediate substrate; mounting a memory device and a logic device on the intermediate substrate such that the memory device and the logic device are adjacent to each other and the memory device or the logic device is adjacent to the optical engine unit; and mounting the intermediate substrate on a package substrate.

According to embodiments of the present disclosure, a method of manufacturing a semiconductor package may be provided and include: manufacturing an optical engine unit including a first redistribution substrate, a photonic integrated circuit (PIC) chip on the first redistribution substrate, an electronic integrated circuit (EIC) chip on the PIC chip, a multi-insulating layer surrounding the PIC chip and the EIC chip, and a transparent support layer on the EIC chip and the multi-insulating layer; mounting the optical engine unit on an intermediate substrate; mounting a memory device and a logic device on the intermediate substrate such that the memory device and the logic device are adjacent to each other and the memory device or the logic device is adjacent to the optical engine unit; and mounting the intermediate substrate on a package substrate.

According to one or more embodiments of the present disclosure, the multi-insulating layer includes a first insulating layer and a second insulating layer on the first redistribution substrate, wherein the forming the optical engine unit includes: preparing the transparent support layer; bonding the EIC chip onto the transparent support layer; forming the second insulating layer surrounding the EIC chip; bonding the PIC chip onto the EIC chip and the second insulating layer; forming the first insulating layer surrounding the PIC chip; forming the first redistribution substrate on the PIC chip and the first insulating layer; and forming a first connection terminal on the first redistribution substrate.

According to one or more embodiments of the present disclosure, the mounting the EIC chip includes bonding an optic path block onto the transparent support layer and adjacent to the EIC chip, and wherein the forming the second insulating layer includes: forming a first insulating material layer on the EIC chip and the optic path block; and completing the second insulating layer by partially removing the first insulating material layer such as to expose the EIC chip and the optic path block.

According to one or more embodiments of the present disclosure, the method further includes forming a microlens in the transparent support layer, wherein the optic path block overlaps with an optical coupler of the PIC chip, and wherein the microlens overlaps with the optic path block.

According to one or more embodiments of the present disclosure, the PIC chip includes a through electrode, wherein the method further includes, before the forming the first insulating layer: thinning the PIC chip by grinding the PIC chip to have a first thickness; and thinning the PIC chip to have a second thickness, different from the first thickness, by etching the PIC chip to expose the through electrode, and wherein the forming the first insulating layer includes: forming a second insulating material layer on the PIC chip; and completing the first insulating layer by partially removing the second insulating material layer such as to expose the PIC chip.

According to one or more embodiments of the present disclosure, the mounting the optical engine unit on the intermediate substrate includes mounting the optical engine unit on the intermediate substrate via the first connection terminal, wherein the mounting of the memory device and the logic device on the intermediate substrate includes mounting the memory device and the logic device on the intermediate substrate via a second connection terminal on the logic device and a third connection terminal on the memory device, and wherein the mounting the intermediate substrate on the package substrate includes mounting the intermediate substrate on the package substrate via a fourth connection terminal on the intermediate substrate.

Aspects of embodiments of the present disclosure are not limited to the foregoing, and other aspects of embodiments of the present disclosure may be clearly understood by a person skilled in the art from the description below.

### BRIEF DESCRIPTION OF DRAWINGS

Embodiments will be more clearly understood from the following detailed description taken in conjunction with the accompanying drawings in which:

FIG. 1A is a cross-sectional view illustrating a semiconductor package according to an embodiment;

FIG. 1B is a cross-sectional view illustrating an enlarged part of an optical engine unit in the semiconductor package of FIG. 1A;

FIGS. 2A to 2C are each a cross-sectional view showing in detail a structure of a second semiconductor device in the semiconductor package of FIG. 1A;

FIGS. 3A and 3B are each a cross-sectional view of a semiconductor package according to an embodiment;

FIGS. 4A and 4B are each a cross-sectional view of a semiconductor package according to an embodiment;

FIGS. 5A and 5B are each a cross-sectional view of a semiconductor package according to an embodiment;

FIGS. 6A to 6E are each a cross-sectional view schematically illustrating a process of manufacturing the semiconductor package of FIG. 1A according to an embodiment;

FIGS. 7A to 7I are each a cross-sectional view schematically illustrating a process of manufacturing an optical engine unit of FIG. 6A; and

FIGS. 8A to 8E are each a cross-sectional view schematically illustrating a process of manufacturing an optical engine unit of the semiconductor package of FIG. 5B.

### DETAILED DESCRIPTION

Hereinafter, non-limiting example embodiments of the present disclosure will be described in detail with reference to the accompanying drawings. Like reference numerals in the drawings denote like elements, and redundant description may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

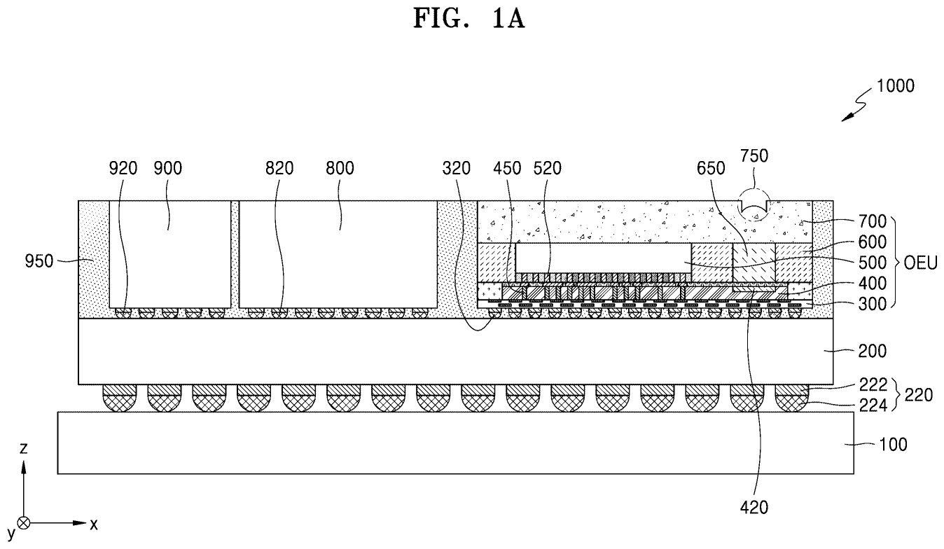

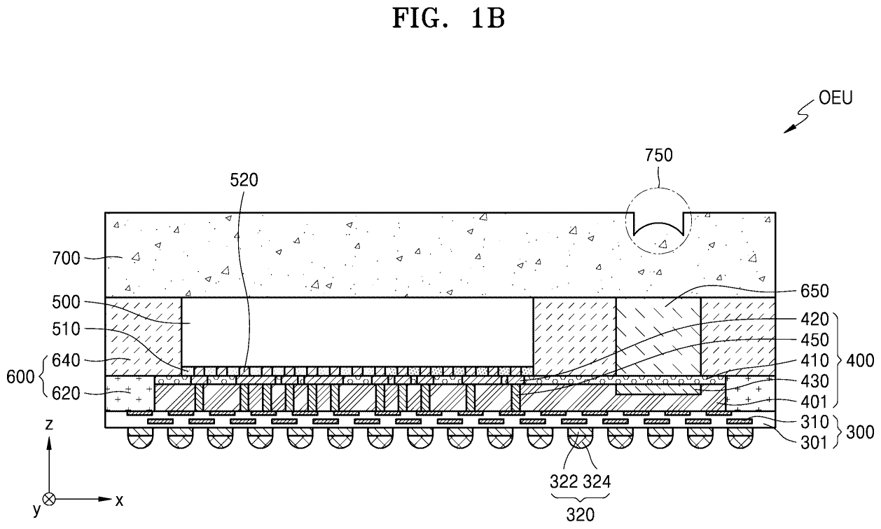

FIG. 1A is a cross-sectional view illustrating a semiconductor package according to an embodiment, and FIG. 1B is a cross-sectional view illustrating an enlarged part of an optical engine unit in the semiconductor package of FIG. 1A.

Referring to FIGS. 1A and 1B, a semiconductor package 1000 according to an embodiment may include a package substrate 100, an interposer 200, an optical engine unit OEU, a first semiconductor device 800, a second semiconductor device 900, and a sealer 950. The semiconductor package 1000 according to an embodiment may be a package for co-packaged optics (CPO). In this regard, the CPO refers to one of heterogeneous integration technologies in which an optical engine (or optical module) is integrated with a switch semiconductor chip on a single package substrate. During the age of artificial intelligence (AI), there have been active research and development in the field of CPO for high-speed and high-efficiency data computation processing.

The package substrate 100 may include, for example, a ceramic substrate, a printed circuit board (PCB), an organic substrate, an interposer substrate, etc. In some embodiments, the package substrate 100 may include an active wafer such as a silicon wafer. In the semiconductor package 1000 according to an embodiment, the package substrate 100 may include a PCB. However, the package substrate 100 is not limited to the PCB.

The package substrate 100 may include a substrate body layer, a protection layer, and a substrate pad. The substrate body layer may constitute a body of the package substrate and may include therein a wiring layer. For example, when the package substrate 100 is a PCB, the substrate body layer may include a core layer and a wiring layer.

The core layer may include glass fiber such as FR4 and resin. In addition, the core layer may include bismaleimide-triazine (BT) resin, poly carbonate (PC) resin, a build-up film such as Ajinomoto build-up film (ABF), or other laminate resin.

The wiring layer may include an upper wiring layer a lower wiring layer with respect to the core layer. The upper wiring layer and the lower wiring layer may each include multi-layer wires. The numbers of the layers of the wires of the upper wiring layer and the lower wiring layer may be identical to or different from each other. In the semiconductor package 1000 according to an embodiment, the wiring layer may include eight to fourteen layers of wires. However, the layers of the wires of the wiring layer is not limited to the numerical range described above.

The wiring layer may include multi-layer wires, an interlayer insulating layer insulating the wires, and a vertical via connecting the wires of different layers to each other. The wires and the vertical via may include, for example, copper (Cu). However, the material of the wires and the vertical via is not limited to Cu. The interlayer insulating layer may include, for example, PrePreg (PPG). The material of the interlayer insulating layer is not limited to PPG.

In some embodiments, the core layer may be omitted. For example, in some embodiments, the package substrate 100 may be a redistribution substrate. In this case, the substrate body layer may not include a separate core layer and include an interlayer insulating layer including photo-imageable dielectric (PID) resin and multilayer-wires.

The protection layer may include an upper protection layer on an upper surface of the substrate body layer and a lower protection layer on a lower surface of the substrate body layer. The protection layer may include, for example, solder resist (SR). However, the material of the protection layer is not limited to SR.

The substrate pad may include an upper substrate pad on the upper surface of the substrate body layer, and a lower substrate pad on the lower surface of the substrate body layer. The upper substrate pad may be arranged to pass through the upper protection layer. The lower substrate pad may be arranged to pass through the lower protection layer. The upper substrate pad and the lower substrate pad may each be connected to the wires of the substrate body layer.

First connection terminals 220 may be arranged on the upper substrate pad, and external connection terminals may be arranged on the lower substrate pad. In FIG. 1A, the external connection terminals are omitted. In general, the external connection terminal may connect the semiconductor package 1000 to a package substrate of an external system or a main board of an electronic apparatus such as a mobile apparatus. The external connection terminal may include a conductive material such as, for example, at least one from among solder, tin (Sn), silver (Ag), copper (Cu), and aluminum (Al). However, the material of the external connection terminal is not limited to the materials described above.

The interposer 200 may be mounted on the package substrate 100 through the first connection terminal 220. The optical engine unit OEU, the first semiconductor device 800, and the second semiconductor device 900 may be stacked on the package substrate 100 with the interposer 200 interposed therebetween. For example, the optical engine unit OEU, the first semiconductor device 800, and the second semiconductor device 900 may be mounted on the interposer 200 and may be electrically connected to the package substrate 100 through the interposer 200.

The interposer 200 may be arranged between the package substrate 100 and the optical engine unit OEU and between the package substrate 100 and the semiconductor devices (e.g., the first semiconductor device 800 and the second semiconductor device 900). For example, the optical engine unit OEU, the first semiconductor device 800, and the second semiconductor device 900 may be arranged on the interposer 200. The interposer 200 may mediate transmission of signals between the first semiconductor device 800 and the second semiconductor device 900, transmission of signals between the optical engine unit OEU and the semiconductor devices (e.g., the first semiconductor device 800 and the second semiconductor device 900), and transmission of signals, power, ground, etc., between the package substrate 100 and the optical engine unit OEU, the first semiconductor device 800, or the second semiconductor device 900. In the semiconductor package 1000 according to an embodiment, the interposer 200 may be an interposer for a 2.5D package. Accordingly, the interposer 200 may include silicon (Si) and may include therein a through silicon via (TSV). However, the interposer 200 in the semiconductor package 1000 is not limited to the interposer for the 2.5D package.

The interposer may include an interposer for a 2.5D package and an interposer for a 2.3D package. The interposer for the 2.5D package generally refers to a Si-interposer and may include therein a TSV. The interposer for the 2.3D package may refer to an organic or inorganic interposer which does not include a TSV. The organic interposer may include polyimide (PI), benzocyclobutene (BCB), or polybenzoxazole (PBO) as a body layer, and the inorganic interposer may include ceramic or glass as a body layer. The interposer for the 2.3D package may also be referred to as a panel level package (PLP) interposer, a redistribution layer (RDL) interposer, etc. The interposer for 2.3D package may include, for example a Si-bridge internally.

The interposer 200 may include a substrate, a through electrode, and a wiring layer. The substrate may include, for example, Si, and accordingly, the interposer 200 may be referred to as a Si-interposer. The through electrode may extend such as to pass through the substrate. As the substrate includes Si, the through electrode may be a TSV. The through electrode may extend to the wiring layer by passing through the substrate and may be electrically connected to the wires of the wiring layer. In some embodiments, the interposer 200 may include only a wiring layer(s) and may not include a through electrode. The wiring layer(s) may be arranged on, under, or on and under the substrate. The pad may be arranged on the upper surface and a lower surface of the interposer 200, and the through electrode may be connected to the pad directly or through the wiring layer.

The first connection terminal 220 may be arranged on the pad on the lower surface of the interposer 200 and may be electrically connected to the through electrode. In addition, the first connection terminal 220 may be connected to the pad on an upper surface of the interposer 200 through the through electrode and the wiring layer. As described above, the interposer 200 may be mounted on the package substrate 100 via the first connection terminal 220. The first connection terminal 220 may include, for example, a pillar 222 and a solder 224. In some embodiments, the first connection terminal 220 may include only a solder.

In the semiconductor package 1000 according to an embodiment, the interposer 200 may be used to transmit an electrical signal among the optical engine unit OEU, the first semiconductor device 800, and the second semiconductor device 900, or to transmit power or ground from the package substrate 100 to the optical engine unit OEU, the first semiconductor device 800, and the second semiconductor device 900. Accordingly, the interposer 200 may not include devices such as an active device, an inactive device, etc. In some embodiments, an underfill may be filled between the interposer 200 and the package substrate 100 and between the first connection terminals 220. When a molded underfill (MUF) process is performed on the package substrate 100, the underfill may be omitted.

With reference to FIG. 1B, the optical engine unit OEU may include a first redistribution substrate 300, a photonic integrated circuit (PIC) chip 400, an electronic integrated circuit (EIC) chip 500, a multi-insulating layer 600, and a transparent support layer 700.

The first redistribution substrate 300 may be arranged under the PIC chip 400 and may redistribute a pad of the PIC chip 400 to the external area of the PIC chip 400. In other words, the first redistribution substrate 300 may be a fan-out redistribution substrate which may be used for extension beyond the footprint of the PIC chip 400. More specifically, the first redistribution substrate 300 may include a first body insulating layer 301 and a first redistribution line 310. The first redistribution line 310 may include multiple layers, and the first redistribution lines 310 of different layers may be connected to each other by a via.

The first body insulating layer 301 may include an insulating material such as, for example, PID resin and may further include an inorganic filler. However, the material of the first body insulating layer 301 is not limited thereto. The first body insulating layer 301 may have a multi-layer structure according to a multi-layer structure of the first redistribution line 310. For convenience, FIGS. 1A and 1B illustrate the first body insulating layer 301 as having a single-layer structure. When the first body insulating layer 301 has a multi-layer structure, the first body insulating layer 301 may include a single material or different materials from each other.

A second connection terminal 320 may be arranged on a lower surface of the first body insulating layer 301. The second connection terminal 320 may be arranged on the pad placed on the lower surface of the first body insulating layer 301. The second connection terminal 320 may be electrically connected to the first redistribution line 310 of the first redistribution substrate 300.

The second connection terminal 320 may be arranged at a portion of the lower surface of the first body insulating layer 301 corresponding to a lower surface of the PIC chip 400 and a portion externally extended from the lower surface in the x direction and the y direction. The first redistribution substrate 300 may rearrange the pad of the PIC chip 400 to a portion horizontally outward of the lower surface of the PIC chip 400 via the first redistribution line 310 and the second connection terminal 320.

The PIC chip 400 may be mounted on the first redistribution substrate 300. The PIC chip 400, which may be an IC chip using light, may be configured for transmission of large-scale information, ultrahigh speed signal processing, minimization of transmission loss, and minimization of energy consumption, etc. The PIC chip 400 may include components such as a light source, an optical waveguide, a passive circuit, a light-current converter, etc. Here, the passive circuit refers to any device that changes characteristics of light and may include a filter, a duplexer, an optical coupler, an interferometer, a spectrometer, etc.

For example, the PIC chip 400 according to an embodiment may include a substrate 401, a protection layer 410, an optical coupler 430, a through electrode 450, the passive circuit, the light source, the optical waveguide, the light-current converter, etc. The substrate 401 may include Si. However, the material of the substrate 401 is not limited to Si.

The through electrode 450 may extend such as to pass through the substrate 401. When the substrate 401 includes Si, the through electrode 450 may be a TSV. The through electrode 450 may be connected to the first redistribution line 310 of the first redistribution substrate 300, which is placed thereunder and may be connected to a pad 420 which is placed thereon. The protection layer 410 may cover an upper surface of the substrate 401. The pad 420 may pass through the protection layer 410 and may be connected to the through electrode 450.

The EIC chip 500 may be mounted on the PIC chip 400 by a pad 520. The pad 520 may include Cu and may be connected to the pad 420 of the PIC chip 400. In some embodiments, micro connection terminals may be arranged on the pad 520. The micro connection terminal may be arranged between the pad 520 of the EIC chip 500 and the pad 420 of the PIC chip 400.

The EIC chip 500 may include various components which facilitate operations of the PIC chip 400. For example, the EIC chip 500 may include a trans-impedance amplifier (TIA), clock and data recovery (CDR), and at least one driver. In some embodiments, the TIA may be a kind of current-voltage converter and may be implemented as at least one operational amplifier. The TIA may amplify a current output of a photodetector or other types of sensors of the PIC chip 400 to a usable voltage. The TIA may provide a lower impedance to a photodiode in the PIC chip 400.

In some embodiment, the CDR may extract timing and data information from a serial data stream in serial communication of digital data. In some embodiments, some high-speed serial data stream may be transmitted without an accompanying clock signal. The CDR may generate a clock from a proper frequency reference and then may phase-adjust the clock in accordance with a switch of the data stream. In some embodiments, the driver may be used to drive various functions of the PIC chip 400.

The multi-insulating layer 600 may be arranged on the first redistribution substrate 300 and may surround the PIC chip 400 and the EIC chip 500. The multi-insulating layer 600 may have a double-layer structure. For example, the multi-insulating layer 600 may include a lower first insulating layer (e.g., a first insulating layer 620) and an upper second insulating layer (e.g., a second insulating layer 640). The multi-insulating layer 600 may include, for example, SiO₂, SiCN, SiON, SiN, polymer, etc. However, the material of the multi-insulating layer 600 is not limited thereto. The multi-insulating layer 600 may be formed by chemical vapor deposition (CVD) or spin coating. However, the method of forming the multi-insulating layer 600 is not limited thereto.

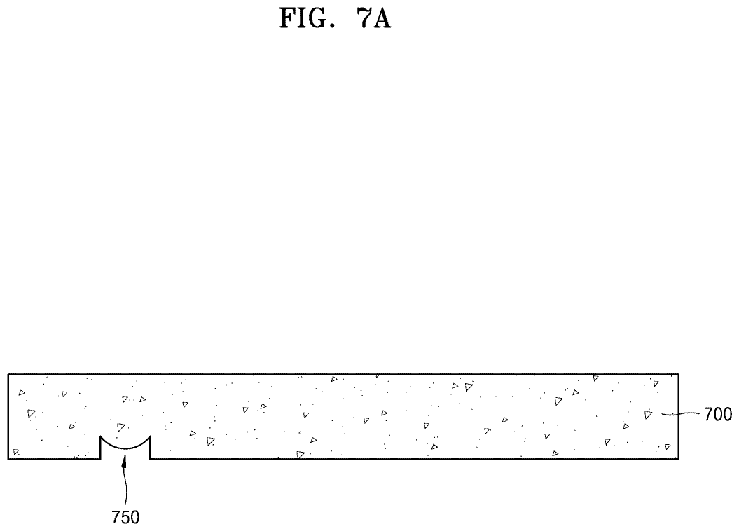

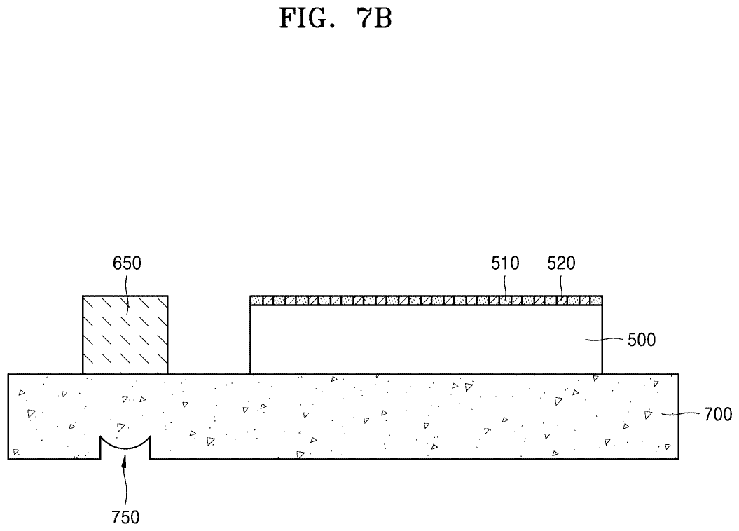

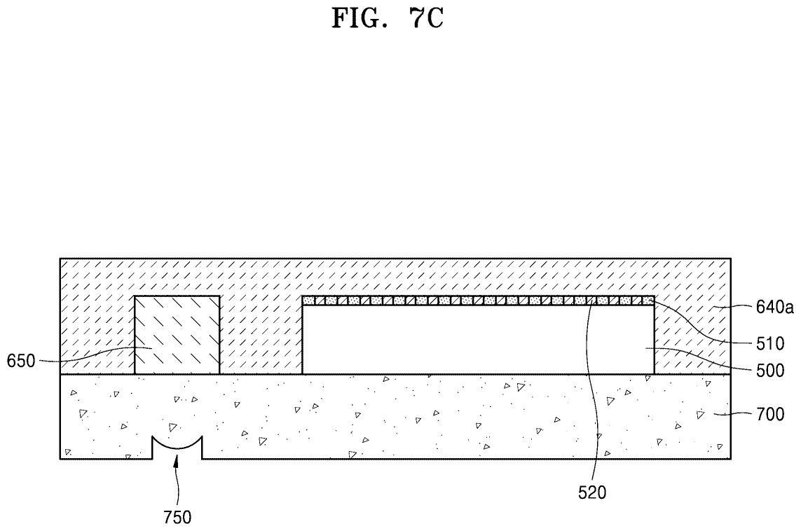

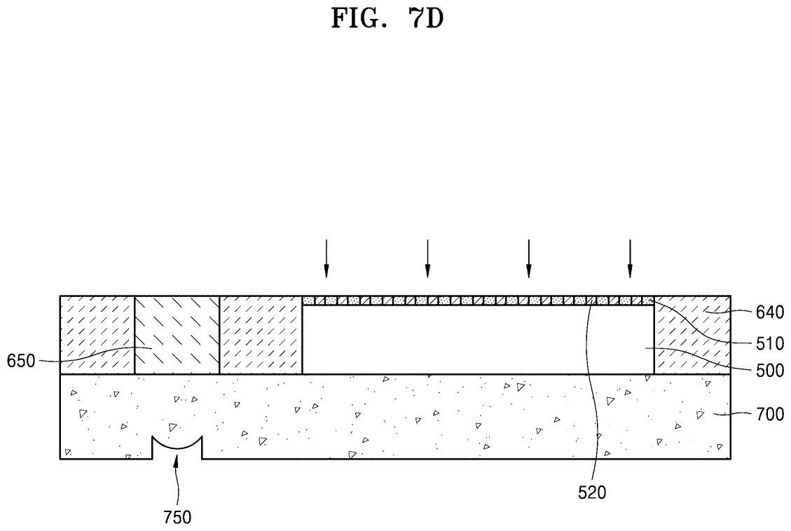

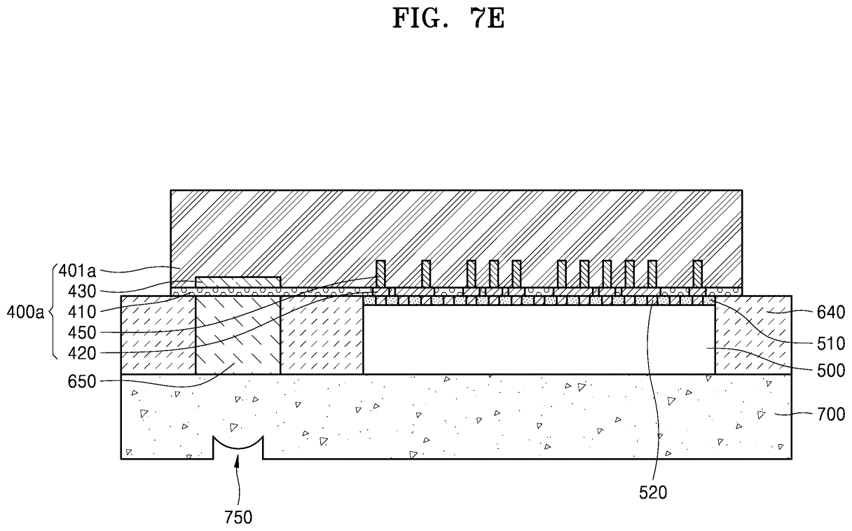

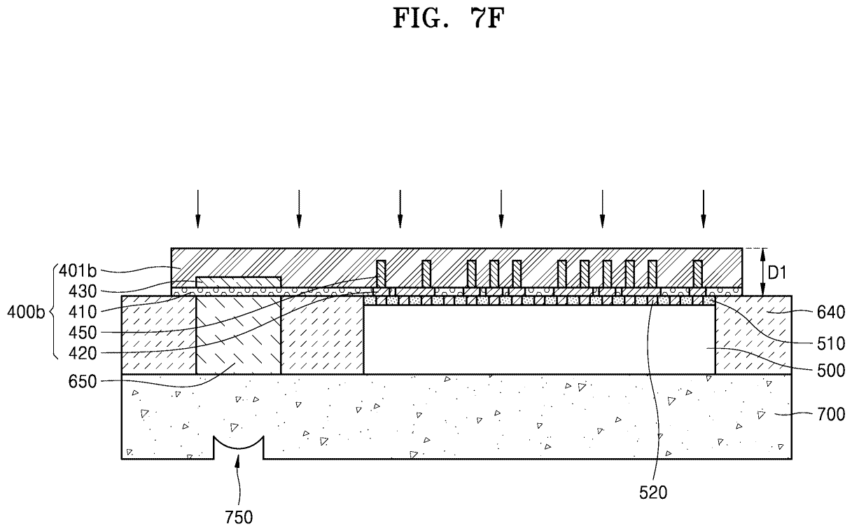

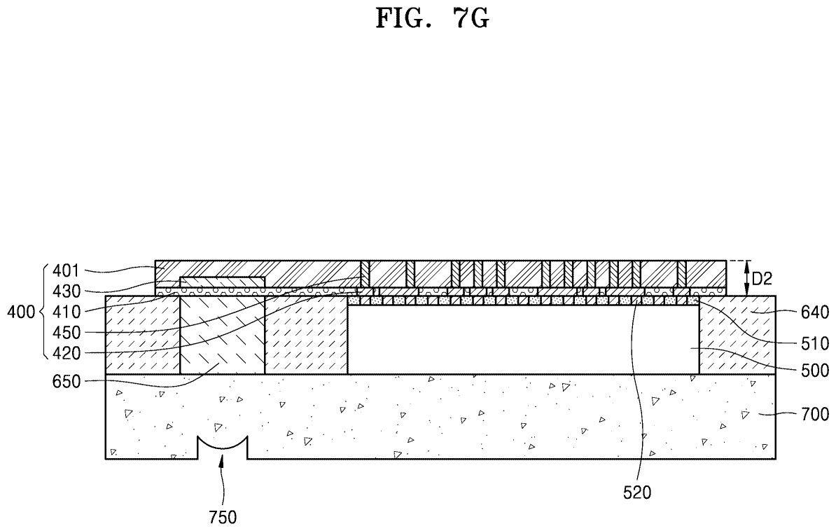

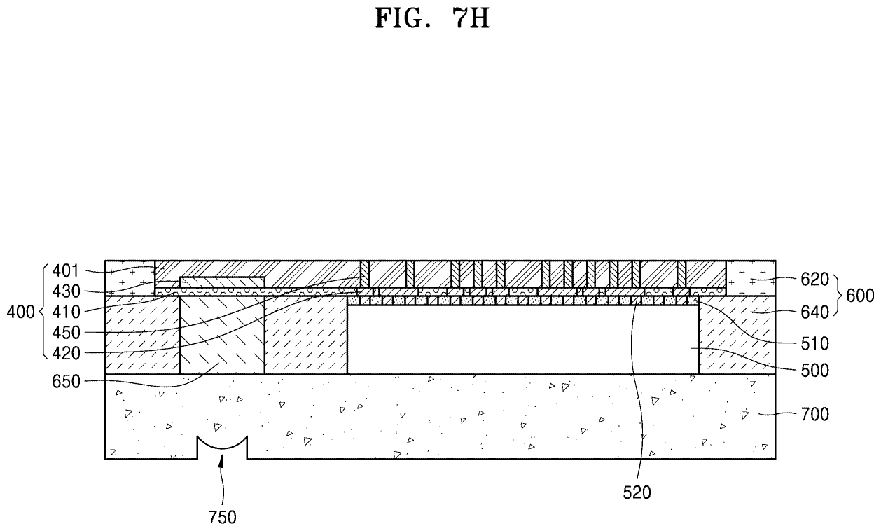

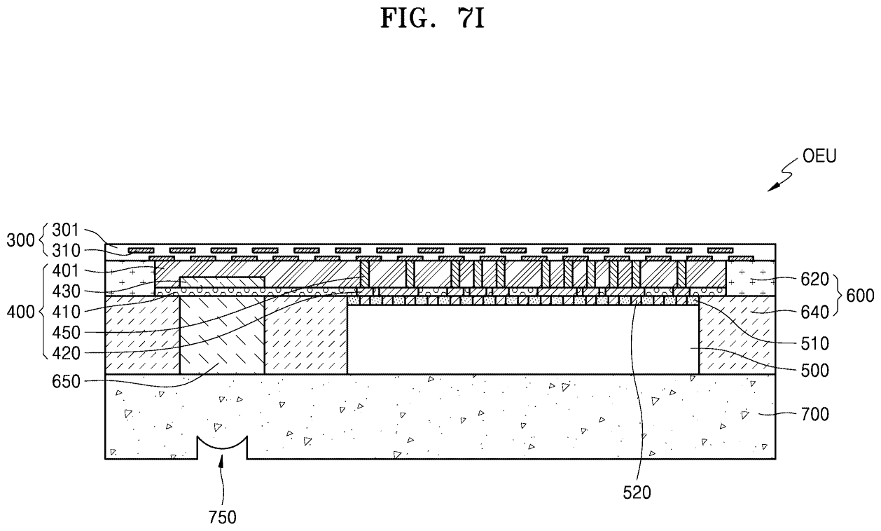

The first insulating layer 620 may surround a lateral surface of the PIC chip 400 on the first redistribution substrate 300. Due to the manufacturing method, an upper surface of the first insulating layer 620 may be substantially coplanar with an upper surface of the PIC chip 400. The second insulating layer 640 may surround a lateral surface of the EIC chip 500 on the first insulating layer 620. Due to the manufacturing method, the upper surface of the second insulating layer 640 may be substantially coplanar with the upper surface of the EIC chip 500. The manufacturing process of the first insulating layer 620 and the second insulating layer 640 will be described in more detail in relation to FIGS. 7A to 7I.

The materials of the first insulating layer 620 and the second insulating layer 640 may be identical to or different from each other. Even when the first insulating layer 620 and the second insulating layer 640 include the same material, the material characteristics thereof may be different from each other due to differences in manufacturing process. For example, when the first insulating layer 620 and the second insulating layer 640 are formed by the CVD process under different process conditions, the stress characteristics of the first insulating layer 620 and the second insulating layer 640 with respect to the compression strength or the tensile strength may be different from each other. As such, due to different materials of the first insulating layer 620 and the second insulating layer 640 or different material characteristics owing to the manufacturing process, there may be an interface between the first insulating layer 620 and the second insulating layer 640.

In the semiconductor package 1000 according to an embodiment, when the stress characteristics of the multi-insulating layer 600 of the optical engine unit OEU are adjusted, the warpage characteristics of the semiconductor package 1000 and/or the optical engine unit OEU may be improved. Accordingly, the reliability of the optical engine unit OEU and/or the semiconductor package 1000 may also be improved.

An optic path block 650 may be arranged in the second insulating layer 640. The optic path block 650 may be arranged at a position where the optical coupler 430 of the PIC chip 400 is arranged and at a position corresponding to a microlens 750 of the transparent support layer 700. More specifically, the optic path block 650 may be arranged on the optical coupler 430. In addition, the optic path block 650 may be arranged at a position where reception of light concentrated through the microlens 750 is optimized. The optic path block 650 may include a transparent material through which light may pass. For example, the optic path block 650 may include Si, SiO₂, glass, transparent polymer, etc. However, the material of the optic path block 650 is not limited thereto.

The transparent support layer 700 may be arranged on the EIC chip 500, the multi-insulating layer 600, and the optic path block 650. The transparent support layer 700 may support main components of the optical engine unit OEU such as, for example, the EIC chip 500, the multi-insulating layer 600, and the optic path block 650. Moreover, the transparent support layer 700 may facilitate external emission of heat generated from the main components of the optical engine unit OEU such as, for example, the EIC chip 500. To maximize the heat emission efficiency of the transparent support layer 700, a thermal interface material (TIM) may be arranged between the transparent support layer 700 and the EIC chip 500. The TIM may be a kind of adhesive that bonds the transparent support layer 700 to the EIC chip 500 and the optic path block 650 and may include a material which is transparent and has excellent heat transfer characteristics. The TIM may include, for example, SiO₂, polymer TIM, thermal grease, optic glue, etc.

The transparent support layer 700 may support optical communication with the PIC chip 400. Accordingly, the transparent support layer 700 may include a material through which light can pass. For example, the transparent support layer 700 may include Si. However, the material of the transparent support layer 700 is not limited to Si. For example, the transparent support layer 700 may include SiO₂, glass, transparent polymer, etc., which may be used in the optic path block 650 and may include other transparent materials. The microlens 750 may be formed on the transparent support layer 700. Through the microlens 750, light for communication may be received and concentrated, and then the light may be transmitted to the optical coupler 430 of the PIC chip 400 through the optic path block 650.

The first semiconductor device 800 may be mounted on the interposer 200 through a third connection terminal 820 (see FIG. 1A). As illustrated in FIG. 1A, the first semiconductor device 800 may be arranged adjacent to the optical engine unit OEU and on the left portion of the interposer 200 in the x direction. The first semiconductor device 800 may also be arranged on the interposer 200 and on the right side of the second semiconductor device 900 in the x direction. That is, the first semiconductor device 800 may be arranged between the optical engine unit OEU and the second semiconductor device 900 on the interposer 200. In some embodiments, the position of the first semiconductor device 800 and the position of the second semiconductor device 900 may be switched in the x direction. For example, the second semiconductor device 900 may be arranged between the optical engine unit OEU and the first semiconductor device 800.

The first semiconductor device 800 may include a logic chip. Accordingly, the first semiconductor device 800 may include a plurality of logic devices. The logic device may refer to a device which performs processing of various signals and may include, for example, AND, OR, NOT, flip-flop, etc. In the semiconductor package 1000 according to an embodiment, the first semiconductor device 800 may include, for example, an application processor (AP), a micro-processor, a central processing unit (CPU), a graphics processing unit (GPU), a controller, or an application specific integrated circuit (ASIC). Accordingly, the first semiconductor device 800 may also be referred to as an AP chip, a process chip, a controller chip, a CPU chip, etc., according to its function. From a viewpoint of an integrated function, the first semiconductor device 800 may be referred to as a system-on-chip (SoC). The first semiconductor device 800 may include devices that support communication. In some embodiments, the devices that support communication may be provided as a separate modem chip or may be combined with the first semiconductor device 800 and arranged on the interposer 200.

The first semiconductor device 800 may include a substrate and a multi-wiring layer. An integrated circuit layer may be formed on an active surface of the substrate. The integrated circuit layer may include a plurality of logic devices. The multi-wiring layer may include multi-layer wires arranged on the lower surface of the substrate. In the first semiconductor device 800, the lower surface may be a front side, which is an active surface, and the upper surface may be a back side, which is an inactive surface. In other words, with respect to the substrate, the lower surface of the substrate where the multi-layer wiring layer is arranged may correspond to the front side of the first semiconductor device 800, and the upper surface of the substrate may correspond to the back side of the first semiconductor device 800.

The second semiconductor device 900 may be mounted on the interposer 200 through a fourth connection terminal 920. As illustrated in FIG. 1A, the second semiconductor device 900 may be arranged adjacent to the first semiconductor device 800 and on the outer left portion of the interposer 200 in the x direction. However, as described above, for example, the position of the second semiconductor device 900 and the position of the first semiconductor device 800 may be switched in the x direction and, in this case, the second semiconductor device 900 may be arranged on the left inner portion of the interposer 200 in the x direction.

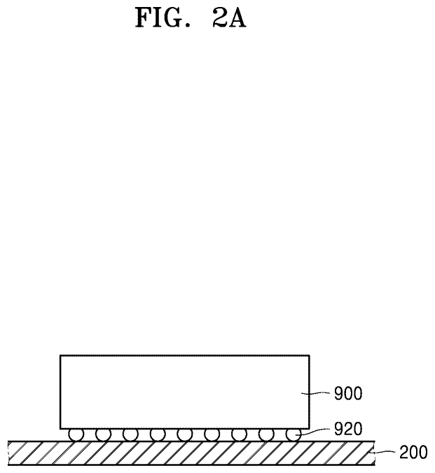

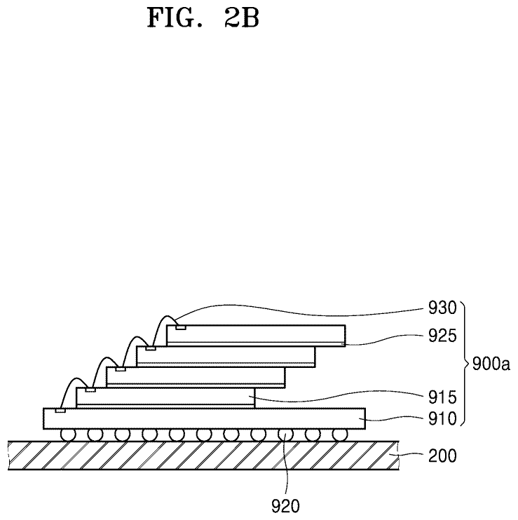

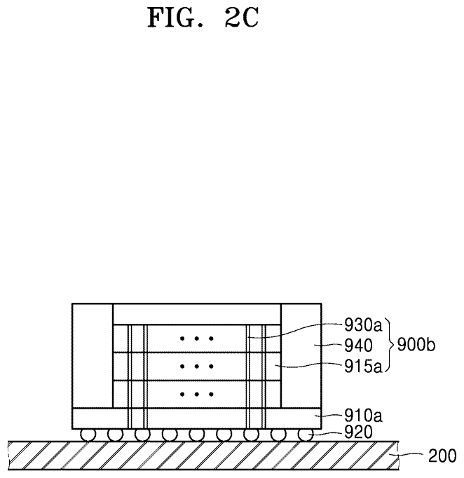

The second semiconductor device 900 may include a volatile memory device such as dynamic random access memory (DRAM), static random access memory (SRAM), etc., or a non-volatile memory device such as flask memory, etc. The second semiconductor device 900 may be a single chip or a package including a plurality of chips. For example, when the second semiconductor device 900 is a single chip, the second semiconductor device 900 may include one memory chip. When the second semiconductor device 900 is a package, the second semiconductor device 900 may include a plurality of memory chips. In the semiconductor package 1000 according to an embodiment, the memory chip of the second semiconductor device 900 may include, for example, a DRAM chip. However, the type of the memory chip of the second semiconductor device 900 is not limited to the DRAM chip. The single chip structure or package structure of the second semiconductor device 900 will be described in more detail in relation to FIGS. 2A to 2C.

In the semiconductor package 1000 according to an embodiment, the second semiconductor device 900 may include a high bandwidth memory (HBM) package as a memory package. However, the second semiconductor device 900 is not limited to the HBM package. For example, the second semiconductor device 900 may have a general package structure as a memory package. For example, the second semiconductor device 900 may include an upper package substrate and a plurality of memory chips stacked on the upper package substrate. In addition, the memory chips may be stacked on the upper package substrate with a bonding wire therebetween or may be stacked on the upper package substrate with a bump and a TSV therebetween.

The sealer 950 may seal the optical engine unit OEU, the first semiconductor device 800, and the second semiconductor device 900 on the interposer 200. More specifically, the sealer 950 may surround a lateral surface of the optical engine unit OEU and may fill a space between the interposer 200 and the optical engine unit OEU and between the second connection terminals 320. In addition, the sealer 950 may surround a lateral surface of each of the first semiconductor device 800 and second semiconductor device 900, and may fill a space between the interposer 200 and the first semiconductor device 800, a space between the interposer 200 and the second semiconductor device 900, a space between the third connection terminals 820, and a space between the fourth connection terminals 920. As illustrated in FIG. 1A, the upper surface of each of the optical engine unit OEU, the first semiconductor device 800, and the second semiconductor device 900 may be exposed from the sealer 950. In some embodiments, except for the optical engine unit OEU, the upper surface of at least one from among the first semiconductor device 800 and the second semiconductor device 900 may be covered by the sealer 950.

The sealer 950 may include an insulating material such as, for example, thermosetting resin such as epoxy resin, thermoplastic resin such as polyimide, or resin obtained by adding a reinforcing agent such as an inorganic filler to the resin described above. For example, the sealer 950 may include ABF, FR-4, BT resin, etc. In addition, the sealer 950 may include a molding material such as epoxy molding compound (EMC) or a photosensitive material such as photo imageable encapsulant (PIE). However, the material of the sealer 950 is not limited thereto.

The semiconductor package 1000 according to an embodiment may be manufactured by arranging the EIC chip 500 and the PIC chip 400 on the transparent support layer 700, and as a process for separately forming the transparent support layer 700 is omitted, the overall process may be simplified. In addition, as the microlens of the transparent support layer 700 is freely formed in a proper stage of the manufacturing process, the degree of freedom of the manufacturing process may increase. As the insulating layer surrounding and sealing the optical engine unit OEU is formed as the multi-insulating layer 600 including two layers, the warpage characteristics of the optical engine unit OEU and/or the semiconductor package 1000 may be improved and, accordingly, the reliability of the optical engine unit OEU and/or the semiconductor package 1000 may be improved as well.

FIGS. 2A to 2C are each a cross-sectional view showing in detail a structure of a second semiconductor device in the semiconductor package of FIG. 1A. Any redundant description made in relation to FIGS. 1A and 1B may be briefly mentioned or omitted.

Referring to FIG. 2A, the second semiconductor device 900 may include one memory chip. The memory chip may include a volatile memory device such as DRAM, SRAM, etc., or a non-volatile memory device such as flash memory, etc. In the semiconductor package 1000 according to an embodiment, the memory chip of the second semiconductor device 900 may include, for example, a DRAM chip. The second semiconductor device 900 may have a flip-chip bonding structure using the fourth connection terminal 920 and may be mounted on the interposer 200. The fourth connection terminal 920 may include a pillar and a solder or may include only a solder.

Referring to FIG. 2B, a second semiconductor device 900a may include a semiconductor package having a wire bonding structure. More specifically, the second semiconductor device 900a may include an upper package substrate 910 and a plurality or memory chips 915 stacked on the upper package substrate 910. The memory chip 915 may be mounted on the upper package substrate 910 in a wire bonding structure using an adhesive layer 925 and a wire 930. The memory chip 915 of the second semiconductor device 900a may include a volatile memory chip such as DRAM, SRAM, etc., or include a non-volatile memory chip such as flask memory, etc. In the semiconductor package 1000 according to an embodiment, the memory chip 915 of the second semiconductor device 900a may include, for example, a DRAM chip. The second semiconductor device 900a may include an internal sealer sealing the memory chips 915 and the wire 930 on the upper package substrate 910. In FIG. 2B, the internal sealer is omitted for convenience.

FIG. 2B illustrates that four memory chips 915 are stacked on the upper package substrate 910; however, the number of the memory chips 915 is not limited to four. For example, three or less memory chips 915 or five or more memory chips 915 may be stacked on the upper package substrate 910. In addition, the memory chips 915 may be stacked on the upper package substrate 910 in a stepped structure, a zigzag structure, or a combination thereof. The second semiconductor device 900a having a package structure may be mounted on the interposer 200 via the fourth connection terminal 920.

Referring to FIG. 2C, a second semiconductor device 900b may include a HBM package. More specifically, the second semiconductor device 900b may include a base chip 910a, a plurality of core chips 915a stacked on the base chip 910a, and an internal sealer 940. In addition, the base chip 910a and the core chips 915a may include therein a through electrode 930a. The uppermost one of the core chips 915a may not include the through electrode 930a.

The base chip 910a may include logic devices. Accordingly, the base chip 910a may be a logic chip. The base chip 910a may be arranged under the core chips 915a, integrate signals of the core chips 915a, transmit the integrated signals to the outside, and transmit a signal and power from the outside to the core chips 915a. Accordingly, the base chip 910a may be referred to as a buffer chip or a control chip. Each of the core chips 915a may be a memory chip. For example, each of the core chips 915a may be a DRAM chip.

Each of the core chips 915a may be stacked on the base chip 910a or a core chip 915a thereunder through pad-to-pad bonding, hybrid bonding (HB), bonding through a connection terminal, or bonding using a anisotropic conductive film (ACF). As the pad may generally include Cu, the pad-to-pad bonding may be referred to as Cu-to-Cu bonding. HB may refer to combined bonding of pad-to-pad bonding and insulator-to-insulator bonding. The ACF, which is an anisotropic conductive film in which electricity flows in one direction, may refer to a conductive film manufactured in the form of film by mixing micro conductive particles with adhesive resin.

FIG. 2C illustrates the four core chips 915a are stacked on the base chip 910a; however, the number of core chips 915a is not limited to four. For example, three or less, or five or more core chips 915a may be stacked on the base chip 910a. The fourth connection terminal 920 may be arranged on the lower surface of the base chip 910a. Accordingly, the second semiconductor device 900b of the HBM package may be mounted on the interposer 200 via the fourth connection terminal 920.

The core chips 915a on the base chip 910a may be sealed by the internal sealer 940. The upper surface of the uppermost one of the core chips 915a may not be covered by the internal sealer 940. In some embodiments, the upper surface of the uppermost one of the core chips 915a may be covered by the internal sealer 940.

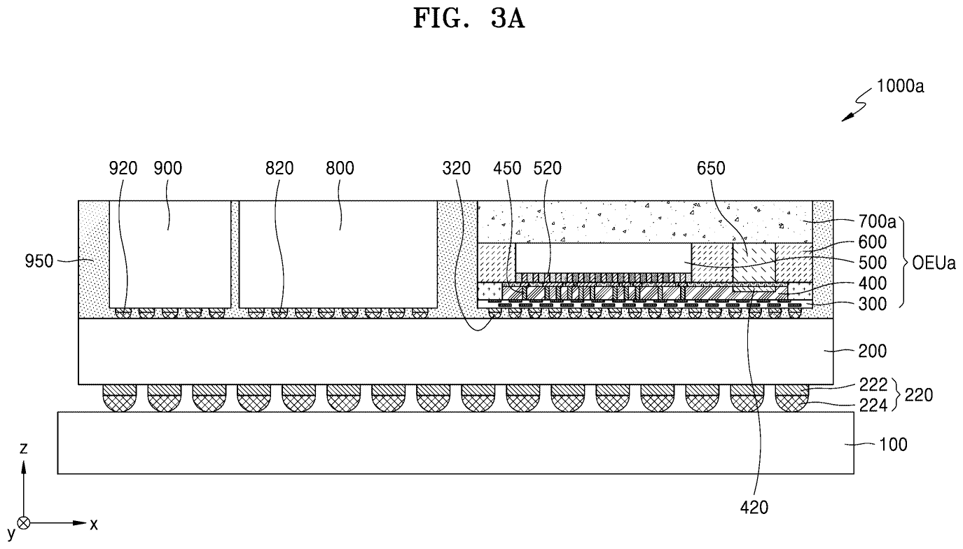

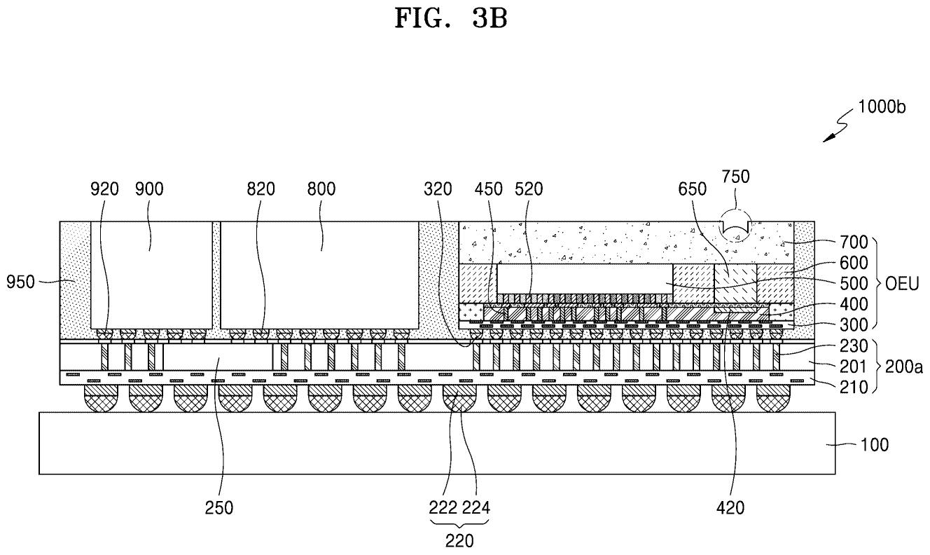

FIGS. 3A and 3B are each a cross-sectional view of a semiconductor package according to an embodiment. Any redundant description made in relation to FIGS. 1A to 2C may be briefly mentioned or omitted.

Referring to FIG. 3A, a semiconductor package 1000a according to an embodiment may be different from the semiconductor package 1000 of FIG. 1A in terms of a structure of an optical engine unit OEUa. More specifically, the semiconductor package 1000a according to an embodiment may include the package substrate 100, the interposer 200, the optical engine unit OEUa, the first semiconductor device 800, the second semiconductor device 900, and the sealer 950. The package substrate 100, the interposer 200, the first semiconductor device 800, the second semiconductor device 900, and the sealer 950 are as described above in relation to the semiconductor package 1000 of FIG. 1A.

The optical engine unit OEUa may include the first redistribution substrate 300, the PIC chip 400, the EIC chip 500, the multi-insulating layer 600, and a transparent support layer 700a. The first redistribution substrate 300, the PIC chip 400, the EIC chip 500, and the multi-insulating layer 600 are as described in relation to the optical engine unit OEU of the semiconductor package 1000 of FIG. 1B.

In the optical engine unit OEUa of the semiconductor package 1000a according to an embodiment, the transparent support layer 700a may not include a separate microlens as illustrated in FIG. 3A. For reference, a semiconductor package for CPO may be combined with a fiber assembly unit (FAU) which transmits light, and when the microlens is not formed in the transparent support layer 700a as in the semiconductor package 1000a according to an embodiment, the microlens may be arranged in the FAU.

Referring to FIG. 3B, a semiconductor package 1000b according to an embodiment may be different from the semiconductor package 1000 of FIG. 1 in that a second redistribution substrate 200a and a Si-bridge 250 are included instead of the interposer 200. More specifically, the semiconductor package 1000b according to an embodiment may include the package substrate 100, the second redistribution substrate 200a, the Si-bridge 250, the optical engine unit OEU, the first semiconductor device 800, the second semiconductor device 900, and the sealer 950. The package substrate 100, the optical engine unit OEU, the first semiconductor device 800, the second semiconductor device 900, and the sealer 950 are as described above in relation to the semiconductor package 1000 of FIG. 1A. In the semiconductor package 1000b according to an embodiment, the optical engine unit OEU, the first semiconductor device 800, and the second semiconductor device 900 may be mounted on the second redistribution substrate 200a, instead of the interposer 200.

The second redistribution substrate 200a may be arranged between the package substrate 100 and the optical engine unit OEU and between the package substrate 100 and the semiconductor devices (e.g., the first semiconductor device 800 and the second semiconductor device 900). For example, the optical engine unit OEU and the semiconductor devices (e.g., the first semiconductor device 800 and the second semiconductor device 900) may be arranged on the second redistribution substrate 200a. The second redistribution substrate 200a may be an RDL interposer and may correspond to the interposer for the 2.3D package described above. Accordingly, the functions of the second redistribution substrate 200a may be similar to those of the interposer 200 of the semiconductor package 1000 of FIG. 1A. However, in the semiconductor package 1000 of FIG. 1A, the transmission of signals between the semiconductor devices (e.g., the first semiconductor device 800 and the second semiconductor device 900) is performed through the interposer 200, whereas in the semiconductor package 1000b according to an embodiment, the transmission of signals between the semiconductor devices (e.g., the first semiconductor device 800 and the second semiconductor device 900) may be performed through the Si-bridge 250 arranged in the second redistribution substrate 200a.

In the semiconductor package 1000b according to an embodiment, the second redistribution substrate 200a may include a redistribution body layer 201, a redistribution layer 210, and a through post 230. The redistribution body layer 201 may include an organic material or an inorganic material as described above.

The redistribution layer 210 may be arranged under the redistribution body layer 201. In some embodiments, the redistribution layer 210 may be arranged on the redistribution body layer 201 or on and under the redistribution body layer 201. The redistribution layer 210 may include an interlayer insulating layer, a redistribution line, and a vertical via. The interlayer insulating layer may include an insulating material such as, for example, PID or photo imageable polyimide (PIP) resin and may further include an inorganic filler. However, the material of the interlayer insulating layer is not limited thereto. For example, the interlayer insulating layer may include polymide isoindro quirazorindione (PIQ), PI, PBO, etc.

The interlayer insulating layer may have a multi-layer structure according to a multi-layer structure of the redistribution line. For convenience, FIG. 3B illustrates that the interlayer insulating layer has a single-layer structure. When the interlayer insulating layer has a multi-layer structure, all layers of the interlayer insulating layer may include the same material, or at least one layer may include a different material.

The redistribution line may be arranged as multiple layers in the interlayer insulating layer. The redistribution lines arranged in different layers may be connected to each other through a vertical via. The redistribution line and the vertical via may include, for example, copper (Cu). However, the material of the redistribution line and the vertical via is not limited to Cu. In FIG. 3B, on the upper surface of the interlayer insulating layer, portions connected to the second connection terminal 320, the third connection terminal 820, and the fourth connection terminal 920 may be considered as a part of the redistribution line or may be referred to as a redistribution pad separately from the redistribution line.

The through post 230 may have an extending structure passing through the redistribution body layer 201. The through posts 230 may electrically connect the redistribution layer 210 to the second connection terminal 320, the third connection terminal 820, and the fourth connection terminal 920. For example, the upper surface of the through posts 230 may be connected to the second connection terminal 320, the third connection terminal 820, and the fourth connection terminal 920, and the lower surface of the through post 230 may be connected to the redistribution line of the redistribution layer 210.

The through post 230 may include, for example, Cu. Accordingly, the through post 230 may be referred to as a Cu post. However, the material of the through post 230 is not limited to Cu. The through post 230 may be formed through electroplating using a seed metal. In the semiconductor package 1000b according to an embodiment, the seed metal may be included as a part of the through post 230.

The Si-bridge 250 may be arranged in the second redistribution substrate 200a. For example, the Si-bridge 250 may be arranged in the redistribution body layer 201 of the second redistribution substrate 200a. The Si-bridge 250 may connect the first semiconductor device 800 to the second semiconductor device 900. Accordingly, the Si-bridge 250 may be arranged in the second redistribution substrate 200a at a portion corresponding to a position between the first semiconductor device 800 and the second semiconductor device 900. Accordingly, the Si-bridge 250 may partially overlap with the first semiconductor device 800 and the second semiconductor device 900.

The Si-bridge 250 may be arranged on the redistribution layer 210. In some embodiments, the redistribution body layer 201 may be maintained at a thin thickness between the Si-bridge 250 and the redistribution layer 210, and the Si-bridge 250 may be arranged on the redistribution body layer 201. The Si-bridge 250 may connect the first semiconductor device 800 to the second semiconductor device 900 through internal wiring. In some embodiments, the Si-bridge 250 may include therein a TSV and may connect the first semiconductor device 800 to the second semiconductor device 900 through the TSV and the redistribution layer 210. In some embodiments, the Si-bridge 250 may include therein a decoupling capacitor, and the decoupling capacitor may be connected to the first semiconductor device 800.

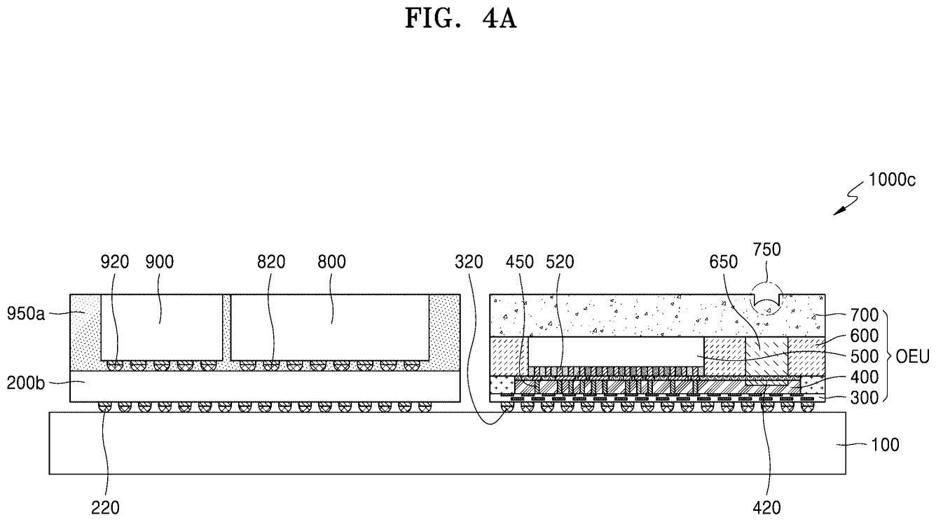

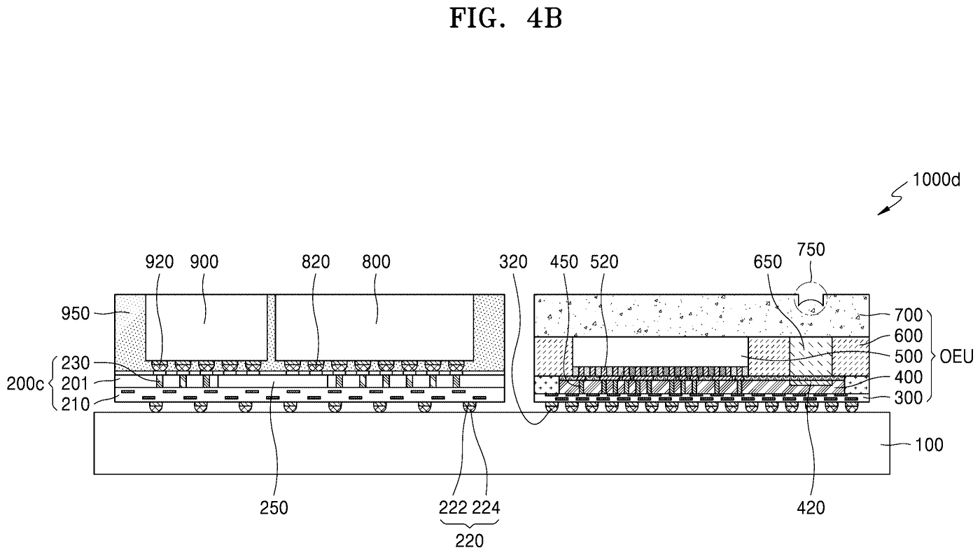

FIGS. 4A and 4B are each a cross-sectional view of a semiconductor package according to an embodiment. Any redundant description made in relation to FIGS. 1A to 3B may be briefly mentioned or omitted.

Referring to FIG. 4A, a semiconductor package 1000c according to an embodiment may be different from the semiconductor package 1000 of FIG. 1A in that a partial interposer 200b is included. More specifically, the semiconductor package 1000c according to an embodiment may include the package substrate 100, the partial interposer 200b, the optical engine unit OEU, the first semiconductor device 800, the second semiconductor device 900, and a sealer 950a. The package substrate 100, the optical engine unit OEU, the first semiconductor device 800, the second semiconductor device 900, and the sealer 950a are as described above in relation to the semiconductor package 1000 of FIG. 1A. In the semiconductor package 1000c according to an embodiment, the optical engine unit OEU may be directly mounted on the package substrate 100 via the second connection terminal 320, and the first semiconductor device 800 and the second semiconductor device 900 may be mounted on the partial interposer 200b. In addition, the sealer 950a may cover the first semiconductor device 800 and the second semiconductor device 900 on the partial interposer 200b. According to embodiments, an external sealer covering a structure on the package substrate 100 may be further included.

The partial interposer 200b may be mounted on the package substrate 100 via the first connection terminal 220. The first semiconductor device 800 and the second semiconductor device 900 may be stacked on the package substrate 100 with the partial interposer 200b interposed therebetween. For example, the first semiconductor device 800 and the second semiconductor device 900 may be mounted on the partial interposer 200b and may be electrically connected to the package substrate 100 through the partial interposer 200b. The partial interposer 200b may mediate the transmission of signals between the first semiconductor device 800 and the second semiconductor device 900 and transmission of signals, power, ground, etc., between the package substrate 100 and the first semiconductor device 800 or the second semiconductor device 900.

In the semiconductor package 1000c according to an embodiment, the partial interposer 200b may have a structure similar to the structure of the interposer 200 of the semiconductor package 1000 of FIG. 1A, except for the size and the connection structure. Accordingly, the partial interposer 200b may be an interposer for a 2.5D package. However, the partial interposer 200b of the semiconductor package 1000c is not limited to the interposer for the 2.5D package.

More specifically, the partial interposer 200b may include a substrate, a through electrode, and a wiring layer. The substrate may include, for example, Si. The through electrode may extend such as to pass through the substrate. As the substrate includes Si, the through electrode may be a TSV. The through electrode may extend to the wiring layer by passing through the substrate and may be electrically connected to the wires of the wiring layer. In some embodiments, the partial interposer 200b may include only a wiring layer and may not include a through electrode. In some embodiments, the partial interposer 200b may not include devices such as an active device or a passive device.

Referring to FIG. 4B, a semiconductor package 1000d according to an embodiment is similar to the semiconductor package 1000c of FIG. 4A; however, the semiconductor package 1000d may be different from the semiconductor package 1000c of FIG. 4A in that a partial redistribution substrate 200c and the Si-bridge 250 are included instead of the partial interposer 200b. More specifically, the semiconductor package 1000d according to an embodiment may include the package substrate 100, the partial redistribution substrate 200c, the Si-bridge 250, the optical engine unit OEU, the first semiconductor device 800, the second semiconductor device 900, and the sealer 950a. The package substrate 100, the optical engine unit OEU, the first semiconductor device 800, the second semiconductor device 900, and the sealer 950a are as described above in relation to the semiconductor package 1000 of FIG. 1A. In the semiconductor package 1000d according to an embodiment, the optical engine unit OEU may be directly mounted on the package substrate 100 via the second connection terminal 320, and the first semiconductor device 800 and the second semiconductor device 900 may be mounted on the partial redistribution substrate 200c. In addition, the sealer 950a may cover the first semiconductor device 800 and the second semiconductor device 900 on the partial redistribution substrate 200c. According to embodiments, an external sealer covering a structure on the package substrate 100 may be further included.

The partial redistribution substrate 200c may be arranged between the package substrate 100 and the semiconductor devices (e.g., the first semiconductor device 800 and the second semiconductor device 900). For example, the semiconductor devices (e.g., the first semiconductor device 800 and the second semiconductor device 900) may be arranged on the partial redistribution substrate 200c. The partial redistribution substrate 200c may be an RDL interposer and may be an interposer for the 2.3D package described above. Accordingly, the functions of the partial redistribution substrate 200c may be similar to the functions of the second redistribution substrate 200a of the semiconductor package 1000b of FIG. 3B.

The partial redistribution substrate 200c may be mounted on the package substrate 100 via the first connection terminal 220. The first semiconductor device 800 and the second semiconductor device 900 may be stacked on the package substrate 100 with the partial redistribution substrate 200c interposed therebetween. For example, the first semiconductor device 800 and the second semiconductor device 900 may be mounted on the partial redistribution substrate 200c via the third connection terminal 820 and the fourth connection terminal 920, and may be electrically connected to the package substrate 100 through the partial redistribution substrate 200c. The partial redistribution substrate 200c may mediate transmission of signals, power, ground, etc., between the package substrate 100 and the first semiconductor device 800 or the second semiconductor device 900. The transmission of signals between the first semiconductor device 800 and the second semiconductor device 900 may be performed through the Si-bridge 250.

In the semiconductor package 1000d according to an embodiment, the partial redistribution substrate 200c may include the redistribution body layer 201, the redistribution layer 210, and the through post 230. The redistribution body layer 201, the redistribution layer 210, and the through post 230 are as described in relation to the second redistribution substrate 200a of the semiconductor package 1000b of FIG. 3B.

The Si-bridge 250 may be arranged in the partial redistribution substrate 200c. For example, the Si-bridge 250 may be arranged in the redistribution body layer 201 of the partial redistribution substrate 200c. The Si-bridge 250 may connect the first semiconductor device 800 to the second semiconductor device 900. Accordingly, the Si-bridge 250 may be arranged in the partial redistribution substrate 200c at a portion corresponding to a position between the first semiconductor device 800 and the second semiconductor device 900. Accordingly, the Si-bridge 250 may partially overlap with the first semiconductor device 800 and the second semiconductor device 900.

The Si-bridge 250 may be arranged on the redistribution layer 210. In some embodiments, the redistribution body layer 201 may be maintained at a thin thickness between the Si-bridge 250 and the redistribution layer 210, and the Si-bridge 250 may be arranged on the redistribution body layer 201. The Si-bridge 250 may connect the first semiconductor device 800 to the second semiconductor device 900 through internal wiring. In some embodiments, the Si-bridge 250 may include therein a TSV and may connect the first semiconductor device 800 to the second semiconductor device 900 through the TSV and the redistribution layer 210. In some embodiments, the Si-bridge 250 may include therein a decoupling capacitor, and the decoupling capacitor may be connected to the first semiconductor device 800.

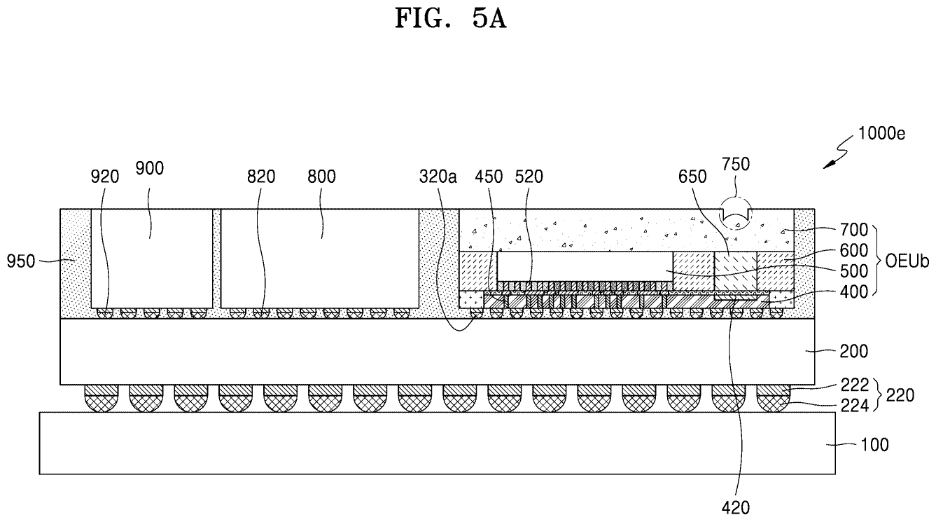

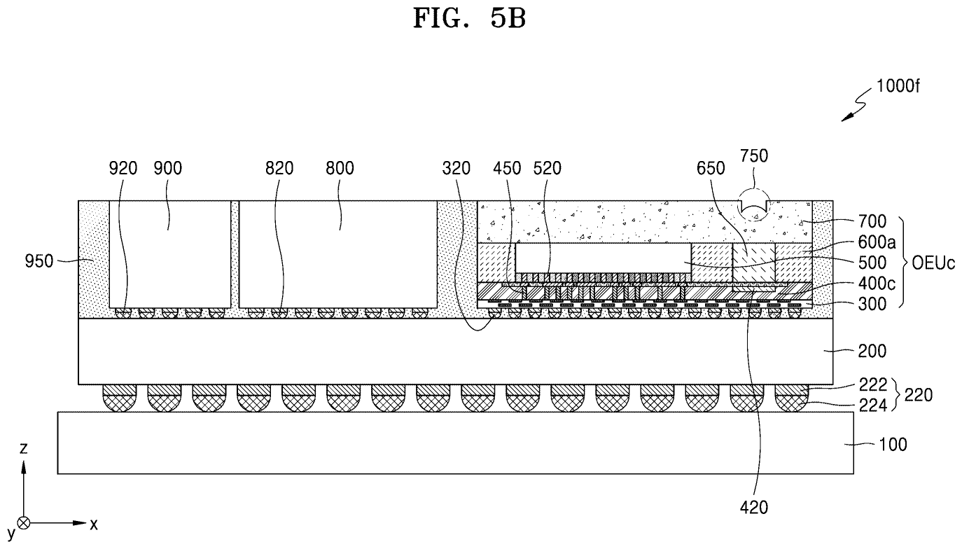

FIGS. 5A and 5B are each a cross-sectional view of a semiconductor package according to an embodiment. Any redundant description made in relation to FIGS. 1A to 4B may be briefly mentioned or omitted.

Referring to FIG. 5A, a semiconductor package 1000e according to an embodiment may be different from the semiconductor package 1000 of FIG. 1A in terms of an optical engine unit OEUb. More specifically, the semiconductor package 1000e according to an embodiment may include the package substrate 100, the interposer 200, the optical engine unit OEUb, the first semiconductor device 800, the second semiconductor device 900, and the sealer 950. The package substrate 100, the interposer 200, the first semiconductor device 800, the second semiconductor device 900, and the sealer 950 are as described above in relation to the semiconductor package 1000 of FIG. 1A.

In the semiconductor package 1000e according to an embodiment, the optical engine unit OEUb may not include a first redistribution substrate. Accordingly, the optical engine unit OEUb may include the PIC chip 400, the EIC chip 500, the multi-insulating layer 600, and the transparent support layer 700. In addition, the optical engine unit OEUb may be directly mounted on the interposer 200 via the second connection terminal 420a arranged under the PIC chip 400. The PIC chip 400, the EIC chip 500, the multi-insulating layer 600, and the transparent support layer 700 are as described in relation to the optical engine unit OEU in the semiconductor package 1000 of FIG. 1A.

The multi-insulating layer 600 of the semiconductor package 1000e according to an embodiment may include the first insulating layer 620 and the second insulating layer 640 (see FIG. 1B). The first insulating layer 620 may surround the lateral surface of the PIC chip 400, and the second insulating layer 640 may surround the lateral surface of the EIC chip 500 on the first insulating layer 620. In the semiconductor package 1000e according to an embodiment, when the stress characteristics of the multi-insulating layer 600 of the optical engine unit OEUb are adjusted, the warpage characteristics of the semiconductor package 1000e and/or the optical engine unit OEUb may be improved. Accordingly, the reliability of the optical engine unit OEUb and/or the semiconductor package 1000e may also be improved.

Referring to FIG. 5B, a semiconductor package 1000f according to an embodiment may be different from the semiconductor package 1000 of FIG. 1A in terms of an optical engine unit OEUc. More specifically, the semiconductor package 1000f according to an embodiment may include the package substrate 100, the interposer 200, the optical engine unit OEUc, the first semiconductor device 800, the second semiconductor device 900, and the sealer 950. The package substrate 100, the interposer 200, the first semiconductor device 800, the second semiconductor device 900, and the sealer 950 are as described above in relation to the semiconductor package 1000 of FIG. 1A.

In the semiconductor package 1000f according to an embodiment, the optical engine unit OEUc may be different from the optical engine unit OEU of the semiconductor package 1000 of FIG. 1A in terms of a PIC chip 400c and an insulating layer 600a. Accordingly, the first redistribution substrate 300, the EIC chip 500, and the transparent support layer 700 are as described in relation to the optical engine unit OEU of the semiconductor package 1000 of FIG. 1A.

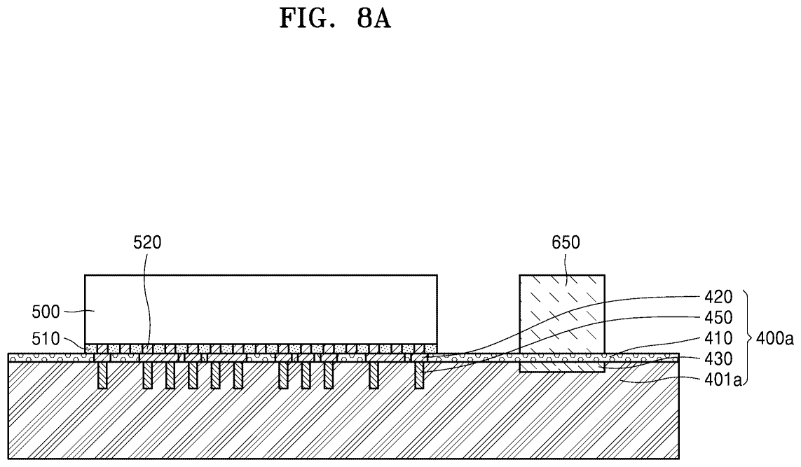

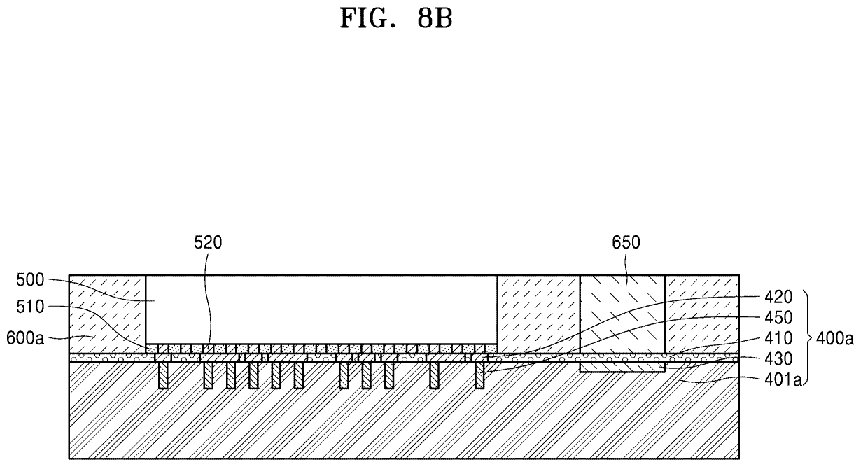

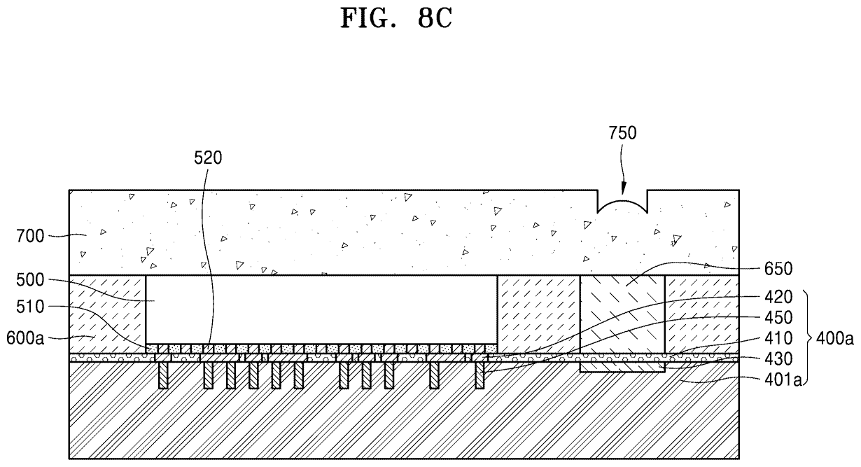

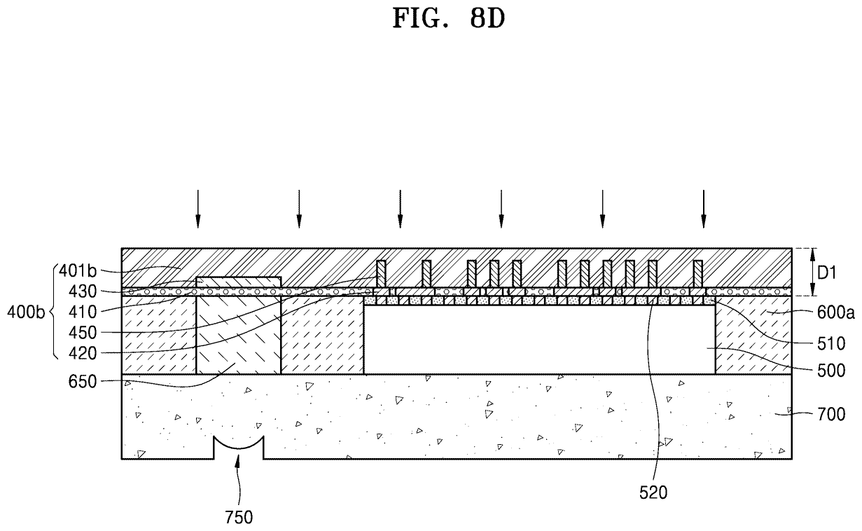

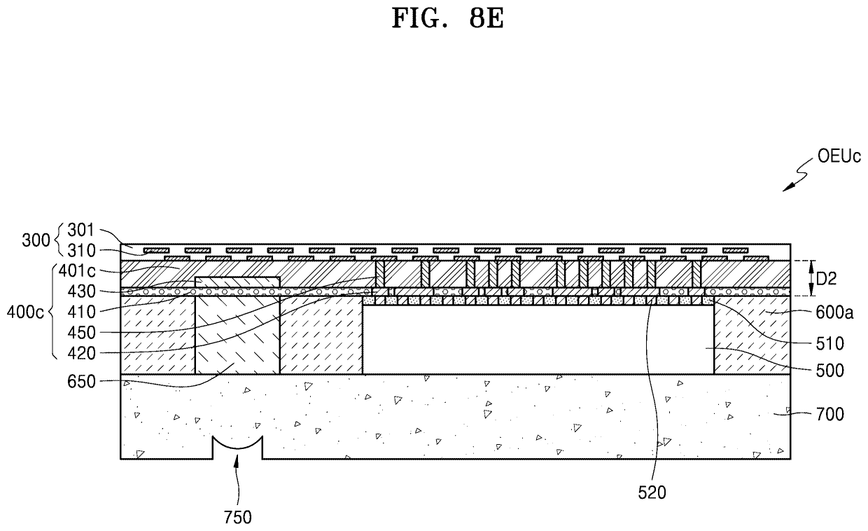

The PIC chip 400c may have the size that entirely covers the upper surface of the first redistribution substrate 300 as illustrated in FIG. 5B. In addition, as the PIC chip 400c entirely covers the upper surface of the first redistribution substrate 300, a portion corresponding to the first insulating layer 620 of the multi-insulating layer 600 of the optical engine unit OEU of FIG. 1A may be omitted. Accordingly, in the optical engine unit OEUc of the semiconductor package 1000f according to an embodiment, the insulating layer 600a may include only a portion corresponding to the second insulating layer 640 of the optical engine unit OEU of FIG. 1A. The structure of the optical engine unit OEUc of the semiconductor package 1000f according to an embodiment may be in accordance with the manufacturing method of the optical engine unit OEUc. A method of manufacturing the optical engine unit OEUc of the semiconductor package 1000f according to an embodiment will be described in more detail in relation to FIGS. 8A to 8E.

A structure in which the optical engine unit (e.g., the optical engine unit OEUb and the optical engine unit OEUc) is mounted on the interposer 200 is described above; however, the structure of the semiconductor package according to an embodiment is not limited thereto. For example, the optical engine unit (e.g., the optical engine unit OEUb and the optical engine unit OEUc) may be mounted on the second redistribution substrate 200a as in the structure of the semiconductor package 1000b of FIG. 3B. In addition, the optical engine unit (e.g., the optical engine unit OEUb and the optical engine unit OEUc) may be mounted on the package substrate 100 as in the structure of the semiconductor package (e.g., the semiconductor package 1000c and the semiconductor package 1000d) of FIG. 4A or 4B.

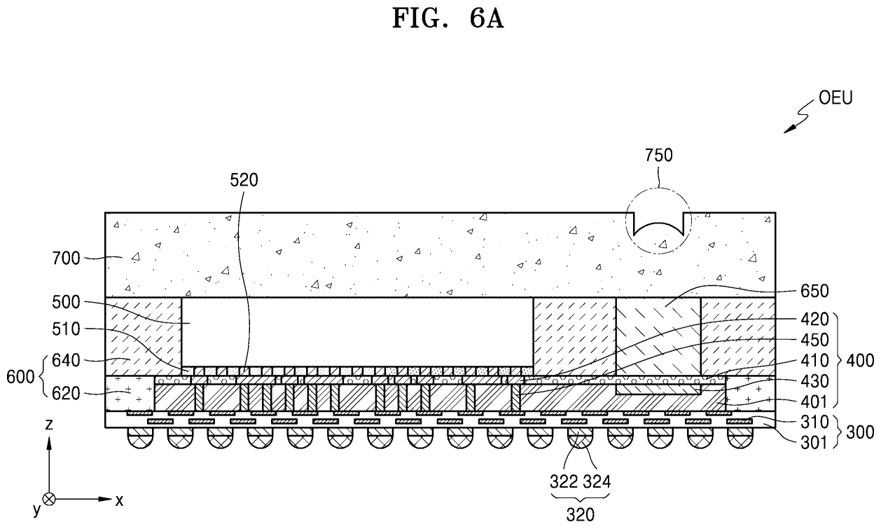

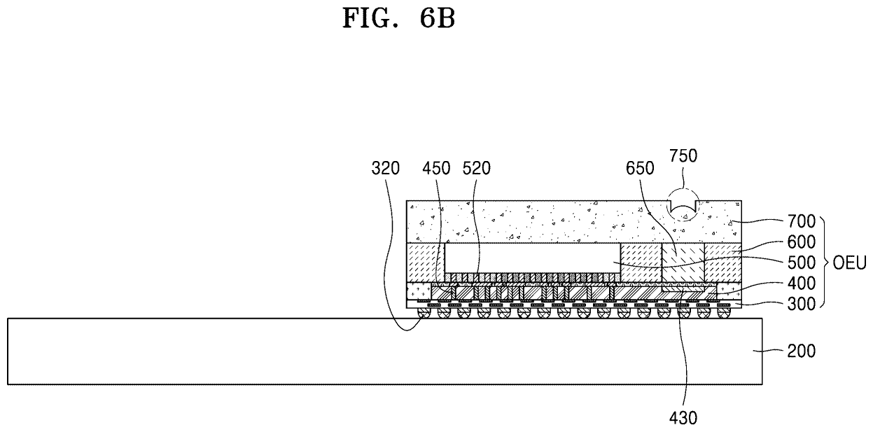

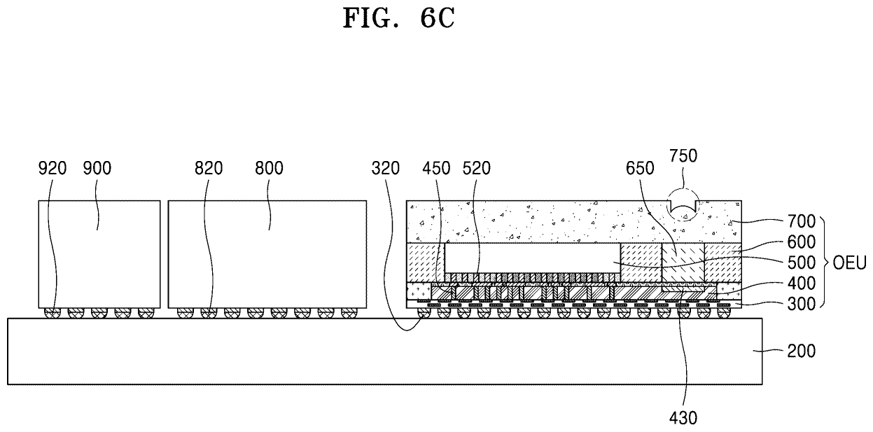

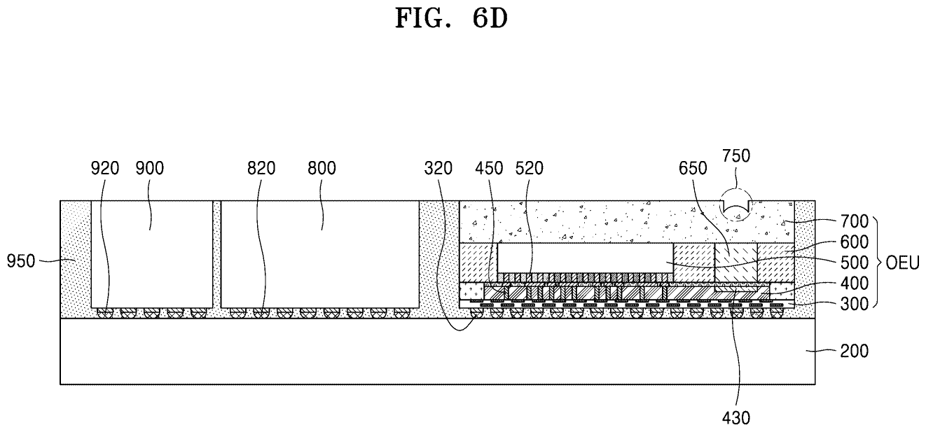

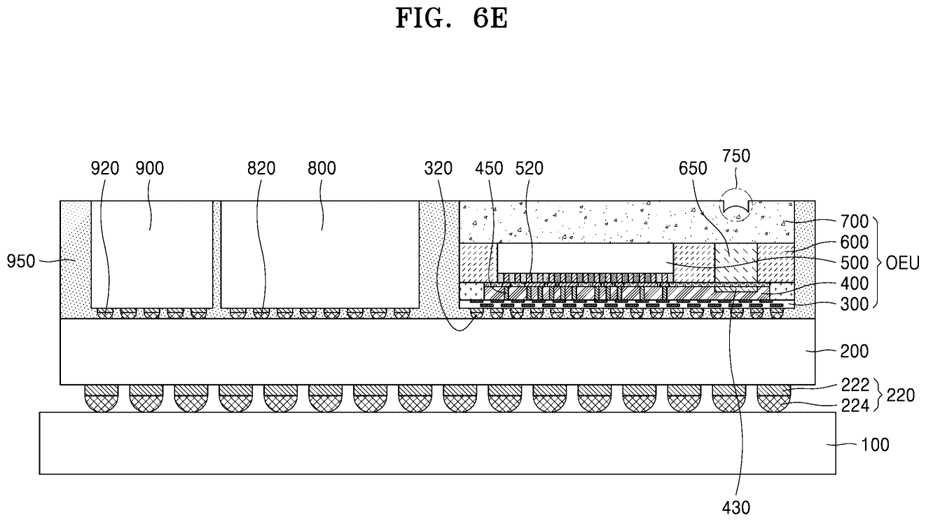

FIGS. 6A to 6E are each a cross-sectional view schematically illustrating a process of manufacturing the semiconductor package of FIG. 1A according to an embodiment. The embodiments are described with reference to FIGS. 1A and 1B, and any redundant description related to FIGS. 1A to 5B may be briefly mentioned or omitted.

Referring to FIG. 6A, in the manufacturing method of the semiconductor device according to an embodiment (e.g., a manufacturing method of the semiconductor package 1000 of FIG. 1A) the optical engine unit OEU may be manufactured first. The optical engine unit OEU may include the first redistribution substrate 300, the PIC chip 400, the EIC chip 500, the multi-insulating layer 600, and a transparent support layer 700. The manufacturing method of the optical engine unit OEU will be described in more detail in relation to FIGS. 7A to 7I. When manufacturing the semiconductor package 1000e of FIG. 5A, the first redistribution substrate 300 may be omitted in the optical engine unit OEU.

Referring to FIG. 6B, after manufacturing the optical engine unit OEU, the optical engine unit OEU may be mounted on the interposer 200 by using the second connection terminal 320. When manufacturing the semiconductor package 1000b, the optical engine unit OEU may be mounted on the second redistribution substrate 200a, and when manufacturing the semiconductor package (e.g., the semiconductor package 1000c and the semiconductor package 1000d) of FIGS. 4A and 4B, the optical engine unit OEU may be directly mounted on the package substrate 100 by using the second connection terminal 320. The interposer 200, the second redistribution substrate 200a, etc., may be manufactured independently from the optical engine unit OEU. In some embodiments, the underfill may be filled between the optical engine unit OEU and the interposer 200.

Referring to FIG. 6C, after mounting the optical engine unit OEU, the semiconductor devices (e.g., the first semiconductor device 800 and the second semiconductor device 900) may be mounted on the interposer 200. More specifically, the first semiconductor device 800 may be mounted on the interposer 200 by using the third connection terminal 820, and the second semiconductor device 900 may be mounted on the interposer 200 by using the fourth connection terminal 920. The order of mounting the first semiconductor device 800 and the second semiconductor device 900 on the interposer 200 may be variously provided. In some embodiments, the underfill may be filled between the first semiconductor device 800 and the interposer 200 and between the second semiconductor device 900 and the interposer 200.

When manufacturing the semiconductor package 1000b of FIG. 3B, the semiconductor devices (e.g., the first semiconductor device 800 and the second semiconductor device 900) may be mounted on the second redistribution substrate 200a, and when manufacturing the semiconductor package (e.g., the semiconductor package 1000c and the semiconductor package 1000d) of FIGS. 4A and 4B, the semiconductor devices (e.g., the first semiconductor device 800 and the second semiconductor device 900) may be mounted on the partial interposer 200b or the partial redistribution substrate 200c.

Referring to FIG. 6D, after mounting the semiconductor devices (e.g., the first semiconductor device 800 and the second semiconductor device 900), the semiconductor devices (e.g., the first semiconductor device 800 and the second semiconductor device 900) and the optical engine unit OEU on the interposer 200 may be sealed with sealer 950. The sealer 950 may surround the lateral surface of each of the first semiconductor device 800, the second semiconductor device 900, and the optical engine unit OEU. The sealer 950 may fill a space between the interposer 200 and the first semiconductor device 800, the second semiconductor device 900, and the optical engine unit OEU. When the underfill is present, the sealer 950 may cover the lateral surface of the underfill.

The upper surface of each of the optical engine unit OEU, the first semiconductor device 800, and the second semiconductor device 900 may be exposed from the sealer 950. In some embodiments, except for the optical engine unit OEU, the upper surface of at least one from among the first semiconductor device 800 and the second semiconductor device 900 may be covered by the sealer 950.

Referring to FIG. 6E, after forming the sealer 950, the interposer 200 and the structure on the interposer 200 may be mounted on the package substrate 100 by using the first connection terminal 220. For reference, the interposer 200 and the structure on the interposer 200 may be referred to as a molded interposer. Through the mounting of the interposer 200 and the structure on the interposer 200 of FIG. 6D, the semiconductor package 1000 of FIG. 1A may be completed.

In FIG. 6D, when the second redistribution substrate 200a of FIG. 3B and the structure of the second redistribution substrate 200a are formed, through the mounting process of FIG. 6E, the semiconductor package 1000b of FIG. 3B may be completed. In FIG. 6D, when the partial interposer 200b of FIG. 4A and the structure on the partial interposer 200b are formed, or the partial redistribution substrate 200c of FIG. 4B and the structure on the partial redistribution substrate 200c are formed, through the mounting process of FIG. 6E, the semiconductor package (e.g., the semiconductor package 1000d and the semiconductor package 1000d) of FIGS. 4A and 4B may be completed. Moreover, when the optical engine unit (e.g., the optical engine unit OEUb and the optical engine unit OEUc) of the semiconductor package (e.g., the semiconductor package 1000e and the semiconductor package 1000f) of FIGS. 5 and 5B is mounted on the interposer 200 in FIG. 6B, through the process of FIGS. 6B to 6D, the semiconductor package (e.g., the semiconductor package 1000e and the semiconductor package 1000f) of FIGS. 5A and 5B may be completed.

FIGS. 7A to 7I are each a cross-sectional view schematically illustrating a process of manufacturing the optical engine unit of FIG. 6A. The embodiments are described with reference to FIGS. 1A and 1B, and any redundant description related to FIGS. 1A to 6E may be briefly mentioned or omitted.

Referring to FIG. 7A, in the manufacturing method of the semiconductor package according to an embodiment, the manufacturing method of the optical engine unit OEU may include preparing the transparent support layer 700. The transparent support layer 700 may be formed from a Si wafer. As illustrated in FIG. 7A, the microlens 750 may be formed in the transparent support layer 700. In other words, the microlens 750 may be formed when the transparent support layer 700 is formed from the Si wafer. However, the time of forming the microlens 750 is not limited thereto. For example, the transparent support layer 700 may be formed without the microlens 750, and the microlens 750 may be formed in the transparent support layer 700 at a proper stage of a subsequent process. Hereinafter, the transparent support layer 700 including the microlens 750 is described.

Referring to FIG. 7B, after forming the transparent support layer 700, the EIC chip 500 and the optic path block 650 are bonded on the transparent support layer 700. The bonding of the EIC chip 500 and the optic path block 650 may be performed by using an adhesive such as TIM. The TIM may include, for example, SiO₂, polymer TIM, thermal grease, optic glue, etc. The order of the bonding the EIC chip 500 and the optic path block 650 on the transparent support layer 700 may be variously provided.

In FIG. 7B, the upper surface of the EIC chip 500 may be an active surface, and the lower surface of the EIC chip 500 may be an inactive surface. Accordingly, the lower surface of the EIC chip 500, which is an inactive surface, may be directed to and bonded on the transparent support layer 700. The protection layer 510 and the pad 520 may be arranged on the upper surface of the EIC chip 500.

The optic path block 650 may be arranged at a position where reception of light concentrated through the microlens 750 is optimized. The optic path block 650 may include a transparent material through which light may pass. For example, the optic path block 650 may include Si, SiO₂, glass, transparent polymer, etc. However, the material of the optic path block 650h is not limited thereto.

Referring to FIG. 7C, after the bonding of the EIC chip 500 and the optic path block 650, a second insulating material layer 640a may be applied. The second insulating material layer 640a may cover the lateral surface and the upper surface of the optic path block 650 and the EIC chip 500. The second insulating material layer 640a may be applied through CVD or spin coating. For example, the second insulating material layer 640a may include SiO₂, SiCN, SiON, SiN, polymer, etc. SiO₂, SiCN, SiON, SiN, etc. may be applied through CVD, and polymer, etc., may be applied through spin coating.

Referring to FIG. 7D, after application of the second insulating material layer 640a, the upper portion of the second insulating material layer 640a may be partially removed to expose the upper surface of the optic path block 650 and the EIC chip 500. The partial removal of the upper portion of the second insulating material layer 640a may be performed through etching and/or chemical mechanical polishing (CMP). Through the partial removal of the upper portion of the second insulating material layer 640a, the second insulating layer 640 may be completed. Accordingly, the upper surface of the optic path block 650 and the EIC chip 500 may be exposed from the second insulating layer 640. The lower surface of the second insulating layer 640 may be substantially coplanar with the lower surface of the optic path block 650 and the EIC chip 500. In addition, the upper surface of the second insulating layer 640 may be substantially coplanar with the upper surface of the optic path block 650 and the EIC chip 500.

Referring to FIG. 7E, after forming the second insulating material layer 640a, an initial PIC chip 400a may be bonded on the EIC chip 500, the optic path block 650, and the second insulating layer 640. The bonding of the initial PIC chip 400a may be performed through hybrid bonding (HB). The BH may include pad-to-pad bonding of the pad 420 of the initial PIC chip 400a and the pad 520 of the EIC chip 500 and insulator-to-insulator bonding of the protection layers. The protection layers may include, for example, a silicon oxide film, a silicon nitride film, an oxynitirde film, etc.

The bonding of the initial PIC chip 400a is not limited to HB. For example, the initial PIC chip 400a may be bonded on the EIC chip 500 through bonding using a connection terminal, bonding using ACF, etc.

In FIG. 7E, the upper surface of the initial PIC chip 400a may be an inactive surface, and the lower surface of the initial PIC chip 400a may be the active surface. Accordingly, the lower surface of the initial PIC chip 400a, which is an active surface, may be directed to the EIC chip 500 and bonded on the EIC chip 500, the optic path block 650, and the second insulating layer 640. In addition, the protection layer 410, the pad 420, the optical coupler 430, and the through electrode 450 may be arranged at the lower portion of the initial PIC chip 400a. Only a substrate 401a including Si may be present at an upper portion of the initial PIC chip 400a, and no other component may be present. For example, the through electrode 450 may be formed in a structure partially passing through a lower portion of the substrate 401a, and may not pass through an upper portion of the substrate 401a.

Referring to FIG. 7F, after the bonding of the initial PIC chip 400a, by partially removing an upper portion of the initial PIC chip 400a, the initial PIC chip 400a may have a first thickness D1. The first thinning process for thinning the initial PIC chip 400a to have the first thickness D1 may be performed through, for example, a grinding process. However, the first thinning process is not limited to the grinding process. Through the first thinning process, an intermediate PIC chip 400b including a substrate 401b having an intermediate thickness of the first thickness D1 may be formed.

Referring to FIG. 7G, after the first thinning process, the upper portion of the intermediate PIC chip 400b may be further removed to expose the upper surface of the through electrode 450 such that the intermediate PIC chip 400b may have a second thickness D2. The second thinning process for thinning the intermediate PIC chip 400b to have the second thickness D2 may be performed by an etching process. The etching process may be, for example, a dry-etching process. However, the etching process is not limited to the dry-etching process. After the second thinning process, the PIC chip 400 may be completed. As illustrated in FIG. 7G, the upper surface of the through electrode 450 may be exposed at the upper surface of the PIC chip 400.

Referring to FIG. 7H, after the second thinning process, the first insulating layer 620 surrounding the PIC chip 400 may be formed on the second insulating layer 640. The method of forming the first insulating layer 620 may be similar to the method of forming the second insulating layer 640. For example, after applying the first insulating material layer to cover the lateral surface and the upper surface of the PIC chip 400, the upper portion of the first insulating material layer may be partially removed to expose the upper surface of the PIC chip 400, thereby completing the first insulating layer 620. The lower surface of the first insulating layer 620 may be substantially coplanar with the lower surface of the PIC chip 400. The upper surface of the first insulating layer 620 may be substantially coplanar with the upper surface of the PIC chip 400.

The materials of the first insulating layer 620 and the second insulating layer 640 may be identical to or different from each other. Even when the first insulating layer 620 and the second insulating layer 640 include the same material, the material characteristics thereof may be different from each other due to differences in manufacturing process. For example, when the first insulating layer 620 and the second insulating layer 640 are formed by the CVD process under different process conditions, the stress characteristics of the first insulating layer 620 and the second insulating layer 640 with respect to the compression strength or the tensile strength may be different from each other. Also, due to different materials of the first insulating layer 620 and the second insulating layer 640 or different material characteristics owing to the manufacturing process, there may be an interface between the first insulating layer 620 and the second insulating layer 640.

Referring to FIG. 7I, after forming the second insulating layer 640, the first redistribution substrate 300 may be formed on the PIC chip 400 and the first insulating layer 620. The first redistribution substrate 300 may include the first body insulating layer 301 and the first redistribution line 310 as described above. After forming the first redistribution substrate 300, by arranging the second connection terminal 320 on the upper surface of the first redistribution substrate 300, the optical engine unit OEU may be completed. For convenience of description, the second connection terminal 320 is omitted in FIG. 7I.

In FIGS. 7A to 7I, the upper and lower portions are reversed as compared to those of the optical engine unit OEU of FIG. 1A or 1B. For example, the lower surface of the transparent support layer 700 of FIG. 7I may correspond to the upper surface of the transparent support layer 700 of the optical engine unit OEU of FIG. 1A or 1B, and the upper surface of the first redistribution substrate 300 of FIG. 7I may correspond to the lower surface of the first redistribution substrate 300 of the optical engine unit OEU of FIG. 1A or 1B. Accordingly, the optical engine unit OEU of FIG. 7I may be mounted on the interposer 200 in a reversed manner via the second connection terminal 320, and then the interposer 200 and the components on the interposer 200 may be mounted on the package substrate 100 through the process of FIGS. 6C to 6E, thereby completing the semiconductor package 1000 of FIG. 1A.

FIGS. 8A to 8E are each a cross-sectional view schematically illustrating a process of manufacturing the optical engine unit of the semiconductor package of FIG. 5B. The embodiments are described with reference to FIG. 5B, and any redundant description related to FIGS. 1A to 7I may be briefly mentioned or omitted.

Referring to FIG. 8A, in the manufacturing method of the semiconductor package according to an embodiment, the manufacturing method of the optical engine unit OEUc may include preparing the initial PIC chip 400a. The initial PIC chip 400a may be the same as described in relation to FIG. 7E. In FIG. 8A, the initial PIC chip 400a may have a greater size than a size of the initial PIC chip 400a of FIG. 7E. For example, the initial PIC chip 400a may be in a state of an unindividualized wafer. In addition, the initial PIC chip 400a of FIG. 8A may be vertically reversed as compared to the initial PIC chip 400a of FIG. 7E. Accordingly, in FIG. 8A, the upper surface of the initial PIC chip 400a may be an active surface, and the lower surface of the initial PIC chip 400a may be an inactive surface.

After preparing the initial PIC chip 400a, the EIC chip 500 may be bonded on the initial PIC chip 400a through HB. However, the bonding of the EIC chip 500 is not limited to HB. For example, the EIC chip 500 may be bonded onto the initial PIC chip 400a through the bonding using a connection terminal, bonding using ACF, etc. In addition, the optic path block 650 may be bonded onto the optical coupler 430 of the initial PIC chip 400a, independently from the bonding of the EIC chip 500.

Referring to FIG. 8B, after the bonding the EIC chip 500 and the optic path block 650, the insulating layer 600a covering the lateral surface of the optic path block 650 and the EIC chip 500 may be formed. The insulating layer 600a may be formed through the method of forming the second insulating layer 640 of FIGS. 7C and 7D. For example, as in FIG. 7C, an insulating material layer covering the lateral surface and the upper surface of the optic path block 650 and the EIC chip 500 may be formed through CVD or spin coating. Then, by partially removing the upper portion of the insulating material layer through etching and/or CMP, etc., the insulating layer 600a may be formed. As illustrated in FIG. 8B, the upper surface of the optic path block 650 and the EIC chip 500 may be exposed from the insulating layer 600a.

Referring to FIG. 8C, after forming the insulating layer 600a, the transparent support layer 700 may be bonded onto the EIC chip 500, the optic path block 650, and the insulating layer 600a. The bonding of the transparent support layer 700 may be performed by using an adhesive such as TIM.

Referring to FIG. 8D, after the bonding of the transparent support layer 700, the whole structure may be reversed and, as illustrated in FIG. 7F, the upper portion of the initial PIC chip 400a may be partially removed through the first thinning process such that the initial PIC chip 400a has the first thickness D1. The first thinning process may be performed through a grinding process. However, the first thinning process is not limited to the grinding process. Through the first thinning process, the intermediate PIC chip 400b including the substrate 401b having an intermediate thickness may be formed.

Referring to FIG. 8E, after the first thinning process, as illustrated in FIG. 7G, the intermediate PIC chip 400b may be thinned to have the second thickness D2 through the second thinning process. After the second thinning process, the PIC chip 400c may be completed. As it may be understood from FIG. 8E, the upper surface of the through electrode 450 may be exposed at the upper surface of the PIC chip 400c.

Then, the first redistribution substrate 300 may be formed on the PIC chip 400c. The first redistribution substrate 300 may include the first body insulating layer 301 and the first redistribution line 310 as described above. After forming the first redistribution substrate 300, by arranging the second connection terminal 320 on the upper surface of the first redistribution substrate 300, the optical engine unit OEUc of the semiconductor package 1000f of FIG. 5B may be completed. For convenience of description, the second connection terminal 320 is omitted in FIG. 8E.

While non-limiting example embodiments of the present disclosure have been particularly shown and described with reference to the drawings, it will be understood that various changes in form and details may be made therein without departing from the spirit and scope of the present disclosure.

What is claimed is:

1. A semiconductor package comprising:
a package substrate;
an intermediate substrate on the package substrate;
an optical engine unit on the intermediate substrate;
a logic device adjacent to the optical engine unit and on the intermediate substrate; and
a memory device adjacent to the logic device and on the intermediate substrate,
wherein the optical engine unit comprises a first redistribution substrate, a photonic integrated circuit (PIC) chip on the first redistribution substrate, an electronic integrated circuit (EIC) chip on the PIC chip, a multi-insulating layer surrounding the PIC chip and the EIC chip, and a transparent support layer on the EIC chip and the multi-insulating layer.

2. The semiconductor package of claim 1, wherein the multi-insulating layer comprises a first insulating layer on the first redistribution substrate and surrounding the PIC chip, and a second insulating layer on the first insulating layer and the PIC chip and surrounding the EIC chip, and
wherein an interface is present between the first insulating layer and the second insulating layer.

3. The semiconductor package of claim 2, wherein the first insulating layer and the second insulating layer comprise different materials from each other or have different physical characteristics from each other.

4. The semiconductor package of claim 2, wherein an upper surface of the first insulating layer is coplanar with an upper surface of the PIC chip, and wherein an upper surface of the second insulating layer is coplanar with an upper surface of the EIC chip.

5. The semiconductor package of claim 1, wherein the multi-insulating layer comprises at least one from among SiO₂, SiCN, SiON, SiNₓ, and a polymer.

6. The semiconductor package of claim 1, wherein the multi-insulating layer comprises an optic path block.

7. The semiconductor package of claim 6, wherein the PIC chip comprises an optical coupler at an upper portion of the PIC chip,
wherein the optic path block is on the optical coupler, and
wherein the transparent support layer comprises a microlens overlapping with the optic path block.

8. The semiconductor package of claim 6, wherein the transparent support layer comprises Si, and
wherein the optic path block comprises at least one from among Si, SiO₂, glass, and a transparent polymer.

9. The semiconductor package of claim 1, wherein the memory device comprises a memory chip or a memory package.

10. The semiconductor package of claim 1, wherein the memory device comprises a high bandwidth memory (HBM) package.

11. The semiconductor package of claim 1, wherein the intermediate substrate comprises a Si-interposer, or a second redistribution substrate and a Si-bridge.

12. A semiconductor package comprising:
a package substrate;
an optical engine unit on the package substrate;
a logic device adjacent to the optical engine unit and on the package substrate; and
a memory device adjacent to the logic device and on the package substrate,
wherein the optical engine unit comprises a first redistribution substrate, a photonic integrated circuit (PIC) chip on the first redistribution substrate, an electronic integrated circuit (EIC) chip on the PIC chip, an insulating layer on the PIC chip, and a transparent support layer on the EIC chip and the insulating layer.

13. The semiconductor package of claim 12, further comprising an intermediate substrate on the package substrate,
wherein the logic device and the memory device are on the intermediate substrate, and
wherein the optical engine unit is directly on the package substrate.

14. The semiconductor package of claim 12, wherein the insulating layer comprises a first insulating layer on the first redistribution substrate and surrounding the PIC chip, and a second insulating layer on the first insulating layer and the PIC chip and surrounding the EIC chip, and
wherein an interface is present between the first insulating layer and the second insulating layer.

15. The semiconductor package of claim 12, wherein the PIC chip comprises an optical coupler at an upper portion of the PIC chip,
wherein the insulating layer comprises an optic path block on the optical coupler, and
wherein the transparent support layer comprises a microlens overlapping with the optic path block.

16. The semiconductor package of claim 12, further comprising an intermediate substrate on the package substrate,
wherein the intermediate substrate comprises a Si-interposer, or a second redistribution substrate and a Si-bridge.

17. A semiconductor package comprising:
a package substrate;
an intermediate substrate on the package substrate;
an optical engine unit on the intermediate substrate;
a logic device adjacent to the optical engine unit and on the intermediate substrate; and
a memory device adjacent to the logic device and on the intermediate substrate,
wherein the optical engine unit comprises:
a first redistribution substrate;
a photonic integrated circuit (PIC) chip on the first redistribution substrate;
an electronic integrated circuit (EIC) chip on the PIC chip;
a first insulating layer on the first redistribution substrate and surrounding the PIC chip;
a second insulating layer on the first insulating layer and the PIC chip and surrounding the EIC chip, the second insulating layer comprising an optic path block; and
a transparent support layer on the EIC chip and the second insulating layer and comprising a microlens overlapping with the optic path block.

18. The semiconductor package of claim 17, wherein an interface is present between the first insulating layer and the second insulating layer, and
wherein the first insulating layer and the second insulating layer comprise different materials from each other or have different physical characteristics from each other.

19. The semiconductor package of claim 17, wherein the intermediate substrate comprises a Si-interposer, or a second redistribution substrate and a Si-bridge.

20. The semiconductor package of claim 17, wherein the memory device comprises a high bandwidth memory (HBM) package.
